(19) United States
(12) Patent Application Publication
(10) Pub. No.: US 2026/0206423 A1
(43) Pub. Date: Jul. 16, 2026

(54) DISPLAY DEVICE, ELECTRONIC DEVICE, AND METHOD OF FABRICATING THE DISPLAY DEVICE

(71) Applicant: Samsung Display Co., Ltd., Yongin-si (KR)

(72) Inventor: Chun Gi YOU, Yongin-si (KR)

(21) Appl. No.: 19/410,522

(22) Filed: Dec. 5, 2025

(30) Foreign Application Priority Data
Jan. 14, 2025 (KR) 10-2025-0005638

(51) Int. Cl. H10K 59/122; H10K 59/12; H10K 59/32; H10K 59/35; H10K 59/80; H10K 102/00

(52) U.S. Cl. CPC H10K 59/122; H10K 59/1201; H10K 59/32; H10K 59/353; H10K 59/80515; H10K 2102/351

(57) ABSTRACT

A display device, an electronic device including the display device, and a method of fabricating the display device are provided. The display device includes a substrate having a display area in which a plurality of subpixels are located, each subpixel of the plurality of subpixels including: a connection electrode on the display area of the substrate; a reflective electrode on the connection electrode; a capping layer on the reflective electrode; and a first electrode on the capping layer; a pixel defining layer on each of the first electrodes of the plurality of subpixels and defining emission areas, the emission areas exposing the first electrodes; a light emitting stack on the first electrodes and the pixel defining layer; and a second electrode on the light emitting stack, wherein the pixel defining layer defines a groove between adjacent first electrodes of the first electrodes.

### CROSS-REFERENCE TO RELATED APPLICATION

The present application claims priority to and the benefit of Korean Patent Application No. 10-2025-0005638, filed on January 14, 2025, in the Korean Intellectual Property Office, the entire disclosure of which is incorporated herein by reference.

### BACKGROUND

### 1. Field

Embodiments of the present disclosure relate to a display device, and for example, to a display device whose reflective electrode can be prevented from being damaged, an electronic device, and a method of fabricating the display device.

### 2. Description of the Related Art

An organic light emitting display apparatus may include a display element whose luminance varies according to an electric current, for example, an organic light emitting diode.

### SUMMARY

Aspects of one or more embodiments of the present disclosure are directed toward a display device whose reflective electrode can be prevented from being damaged or for which damage may be reduced, an electronic device including the display device, and a method of fabricating the display device.

Aspects of one or more embodiments of the present disclosure are directed toward a display device in which damage to a reflective electrode can be prevented or reduced, an electronic device including the display device, and a method of fabricating the display device. For example, if (e.g., when) a pixel defining layer is formed without a planarization process, damage to the reflective electrode by a cleaning solution (or cleaning gas) can be prevented or reduced.

Additional aspects will be set forth in part in the description which follows and, in part, will be apparent from the description, or may be learned by practice of the presented embodiments of the disclosure.

According to one or more embodiments of the present disclosure, there is provided a display device including: a substrate having a display area in which a plurality of subpixels are located, each subpixel of the plurality of subpixels including: a connection electrode on the display area of the substrate; a reflective electrode on the connection electrode; a capping layer on the reflective electrode; and a first electrode on the capping layer; a pixel defining layer on each of the first electrodes of the plurality of subpixels and defining emission areas, the emission areas exposing the first electrodes; a light emitting stack on the first electrodes and the pixel defining layer; and a second electrode on the light emitting stack, wherein the pixel defining layer defines a groove between adjacent first electrodes of the first electrodes.

According to one or more embodiments of the present disclosure, there is provided an electronic device including a display device which includes a screen, wherein the display device includes: a substrate having a display area in which a plurality of subpixels are located, each subpixel of the plurality of subpixels including: a connection electrode on the display area of the substrate; a reflective electrode on the connection electrode; a capping layer on the reflective electrode; and a first electrode on the capping layer; a pixel defining layer on each of the first electrodes of the plurality of subpixels and defining emission areas, the emission areas exposing the first electrodes; a light emitting stack on the first electrodes and the pixel defining layer; and a second electrode on the light emitting stack, wherein the pixel defining layer defines a groove between adjacent first electrodes of the first electrodes.

According to one or more embodiments of the present disclosure, there is provided a method of fabricating a display device including a plurality of subpixels. The method includes: forming a connection electrode layer on an insulating layer on a substrate; forming a reflective electrode layer on the connection electrode layer; forming a buffer layer on the reflective electrode layer; removing the buffer layer on a display area of the substrate by patterning the buffer layer; forming an auxiliary layer on an entire surface of the substrate including the reflective electrode layer; forming a capping layer, a reflective electrode and a connection electrode for each subpixel of the plurality of subpixels and exposing the insulating layer by patterning the auxiliary layer, the reflective electrode layer, and the connection electrode layer; forming a first electrode layer on the entire surface of the substrate including the capping layer and the insulating layer; forming a first defining layer on the entire surface of the substrate including the first electrode layer; forming a first defining layer and a first electrode for each subpixel and exposing the insulating layer by patterning the first defining layer and the first electrode layer; forming a second defining layer on the entire surface of the substrate including the patterned first defining layer and the first electrode; forming a third defining layer on the entire surface of the substrate including the second defining layer; forming a first bank layer on the entire surface of the substrate including the third defining layer; forming a second bank layer on the entire surface of the substrate including the first bank layer; forming a separator having a first bank and a second bank and exposing the third defining layer in each subpixel by patterning the second bank layer and the first bank layer together; and forming a pixel defining layer having emission areas which expose the first electrode of each subpixel by patterning the third defining layer, the second defining layer, and the first defining layer, wherein the pixel defining layer has a groove between adjacent first electrodes of the first electrodes of the plurality of subpixels.

The effects of the present disclosure are not limited to the above-described effects and other effects which are not described herein will become apparent to those skilled in the art from the following description.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is an exploded perspective view of a display device according to one or more embodiments of the present disclosure;

FIG. 2 is a block diagram of the display device according to one or more embodiments of the present disclosure;

FIG. 3 is an equivalent circuit diagram of a first subpixel according to one or more embodiments of the present disclosure;

FIG. 4 is a layout view of a display panel according to one or more embodiments of the present disclosure;

FIGS. 5 and 6 are each a layout view of a display area of FIG. 4, according to one or more embodiments of the present disclosure;

FIG. 7 is a cross-sectional view of the display panel taken along the line I1-I1’ of FIG. 5, according to one or more embodiments of the present disclosure;

FIG. 8 is a detailed cross-sectional view of the area A1 of FIG. 7, according to one or more embodiments of the present disclosure;

FIG. 9 is a detailed cross-sectional view of the area A2 of FIG. 8, according to one or more embodiments of the present disclosure;

FIGS. 10 to 18 are cross-sectional views illustrating a method of fabricating a display device, according to one or more embodiments of the present disclosure;

FIG. 19 is a block diagram of an electronic device, according to one or more embodiments of the present disclosure; and

FIGS. 20, 21, and 22 are schematic diagrams of electronic devices, according to embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided. In the drawings, the relative sizes (e.g., including lengths, widths and thicknesses) of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The terms "first", "second", etc. may also be used herein to differentiate different categories or sets of elements. For conciseness, the terms "first", "second", etc. may represent "first-category (or first-set)", "second-category (or second-set)", etc., respectively.

Spatially relative terms, such as “on,” “lower,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the singular forms “a,” “an” and “the” are intended to include the plural forms as well, unless the context clearly indicates otherwise. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions "at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

Features of various embodiments of the present disclosure may be combined partially or totally. As will be clearly appreciated by those skilled in the art, technically various interactions and operations are possible. Various embodiments can be practiced individually or in combination.

Hereinafter, specific embodiments will be described with reference to the accompanying drawings.

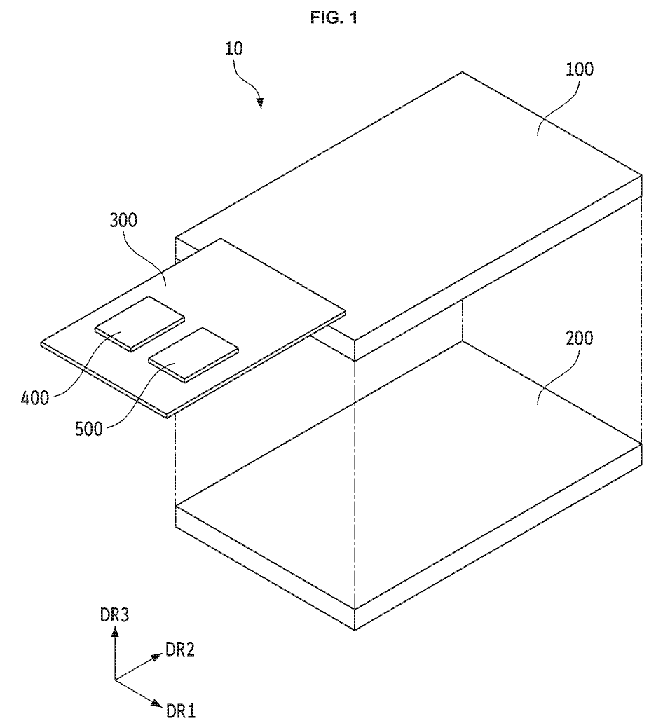

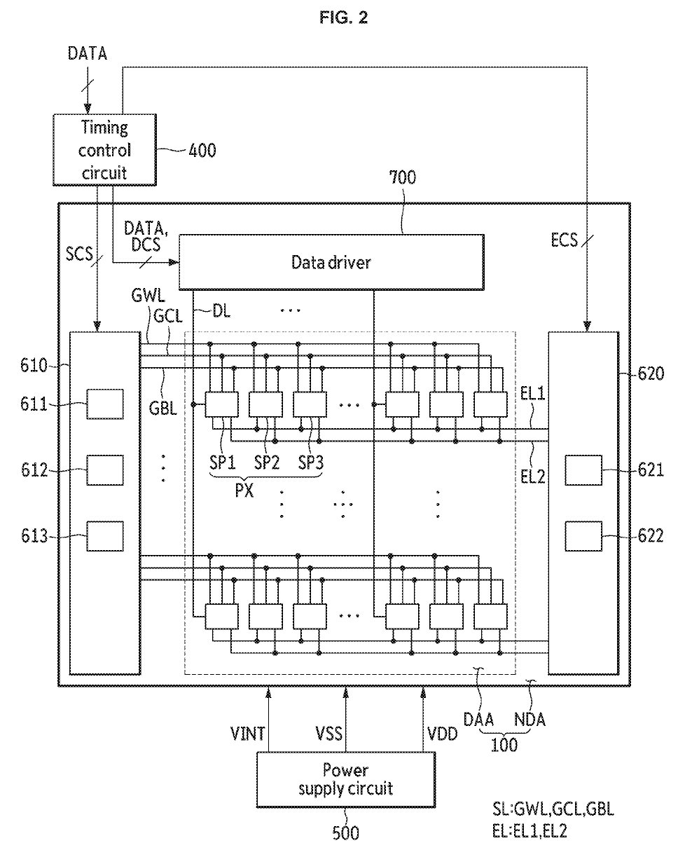

FIG. 1 is an exploded perspective view of a display device 10 according to one or more embodiments of the present disclosure. FIG. 2 is a block diagram of the display device 10 according to one or more embodiments of the present disclosure.

Referring to FIGS. 1 and 2, the display device 10 according to one or more embodiments is a device for displaying moving images or still images. The display device 10 according to one or more embodiments may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 according to one or more embodiments may be applied as a display unit of a television, a notebook computer, a monitor, a billboard, or an Internet of things (IoT) device. Alternatively, the display device 10 according to one or more embodiments may be applied to smart watches, watch phones, and head mounted displays for implementing virtual reality and augmented reality.

The display device 10 according to one or more embodiments may include a display panel 100, a heat dissipation layer 200, a circuit board 300, a timing control circuit 400, and a power supply circuit 500.

The display panel 100 may have a planar shape similar to a quadrangle. For example, the display panel 100 may have a planar shape similar to a quadrangle having short sides in a first direction DR1 and long sides in a second direction DR2 intersecting the first direction DR1. In the display panel 100, each corner where a short side extending in the first direction DR1 meets a long side extending in the second direction DR2 may be rounded with a selected curvature or may be right-angled. The planar shape of the display panel 100 is not limited to a quadrangular shape and may also be similar to other polygonal shapes, a circular shape, or an oval shape. The planar shape of the display device 10 may follow the planar shape of the display panel 100, but of the present disclosure is not limited thereto.

The display panel 100 includes a plurality of pixels PX, a plurality of scan lines SL, a plurality of emission control lines EL, a plurality of data lines DL, a scan driver 610, an emission driver 620, and a data driver 700. As illustrated in FIG. 2, the display panel 100 may be divided into a display area DAA displaying an image and a non-display area NDA not displaying an image.

The pixels PX may be arranged in the display area DAA. The pixels PX may be arranged in a matrix form in the first direction DR1 and the second direction DR2. The scan lines SL and the emission control lines EL may extend in the first direction DR1 and may be arranged in the second direction DR2. The data lines DL may extend in the second direction DR2 and may be arranged in the first direction DR1.

The scan lines SL may include a plurality of write scan lines GWL, a plurality of control scan lines GCL, and a plurality of bias scan lines GBL. The emission control lines EL may include a plurality of first emission control lines EL1 and a plurality of second emission control lines EL2.

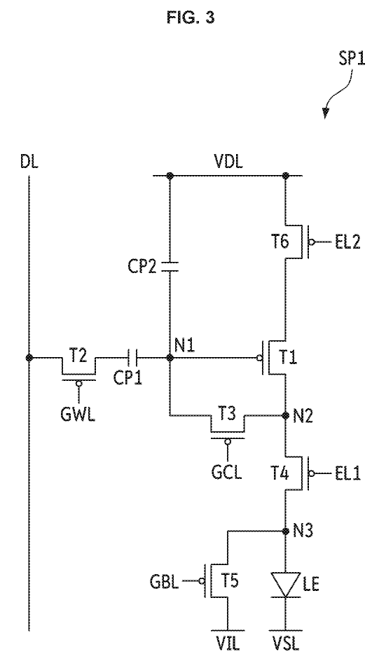

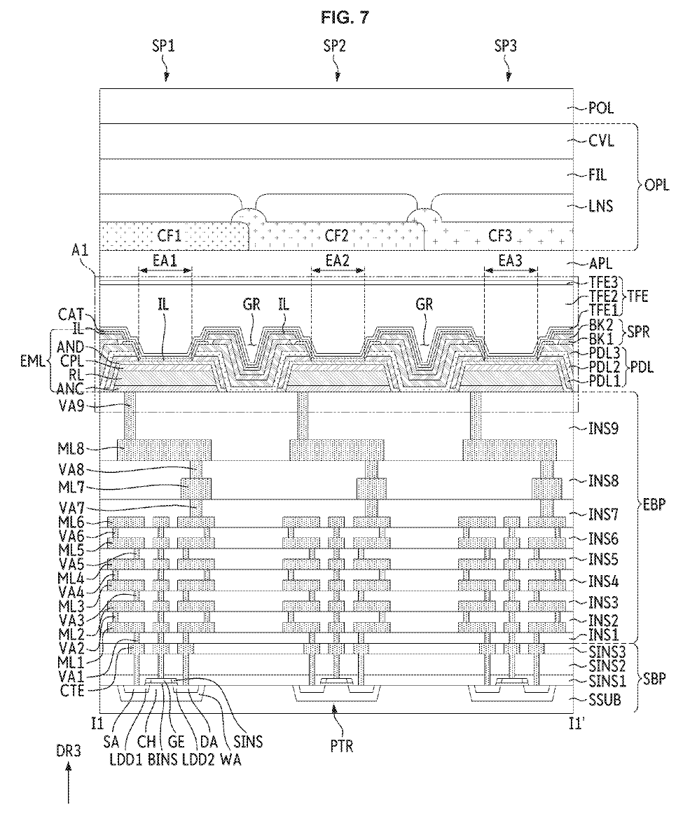

Each of the pixels PX may include a plurality of subpixels SP1 through SP3. Each of the subpixels SP1 through SP3 includes a plurality of pixel transistors as illustrated in FIG. 3. The pixel transistors may be formed through a semiconductor process and may be located in a semiconductor substrate SSUB (see, e.g., FIG. 7).

Each of the subpixels SP1 through SP3 may be connected to any one of the write scan lines GWL, any one of the control scan lines GCL, any one of the bias scan lines GBL, any one of the first emission control lines EL1, any one of the second emission control lines EL2, and any one of the data lines DL. Each of the subpixels SP1 through SP3 may receive a data voltage of a data line DL according to a write scan signal of a write scan line GWL and may emit light from a light emitting element according to the data voltage.

The scan driver 610, the emission driver 620, and the data driver 700 may be located in the non-display area NDA.

The scan driver 610 includes a plurality of scan transistors, and the emission driver 620 includes a plurality of emission transistors. The scan transistors and the emission transistors may be formed through a semiconductor process and may be formed in the semiconductor substrate SSUB (see, e.g., FIG. 7). For example, the scan transistors and the emission transistors may be formed as CMOS transistors, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The emission driver 620 includes a first emission control driving unit 621 and a second emission control driving unit 622. Each of the first emission control driving unit 621 and the second emission control driving unit 622 may receive an emission timing control signal ECS from the timing control circuit 400. The first emission control driving unit 621 may generate first emission control signals according to the emission timing control signal ECS and sequentially output the first emission control signals to the first emission control lines EL1. The second emission control driving unit 622 may generate second emission control signals according to the emission timing control signal ECS and sequentially output the second emission control signals to the second emission control lines EL2.

The data driver 700 includes a plurality of data transistors. The data transistors may be formed through a semiconductor process and may be formed in the semiconductor substrate SSUB (see, e.g., FIG. 7). For example, the data transistors may be formed as CMOS transistors, but the present disclosure is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In such embodiments, subpixels SP1 through SP3 may be selected by a write scan signal of the scan driver 610, and the data voltages may be supplied to the selected subpixels SP1 through SP3.

The heat dissipation layer 200 may overlap the display panel 100 in a third direction DR3 which is a thickness direction of the display panel 100. The heat dissipation layer 200 may be located on a surface, e.g., a back surface of the display panel 100. The heat dissipation layer 200 dissipates heat generated from the display panel 100. The heat dissipation layer 130 may include a metal layer having high thermal conductivity, such as graphite, silver (Ag), copper (Cu), and/or aluminum (Al).

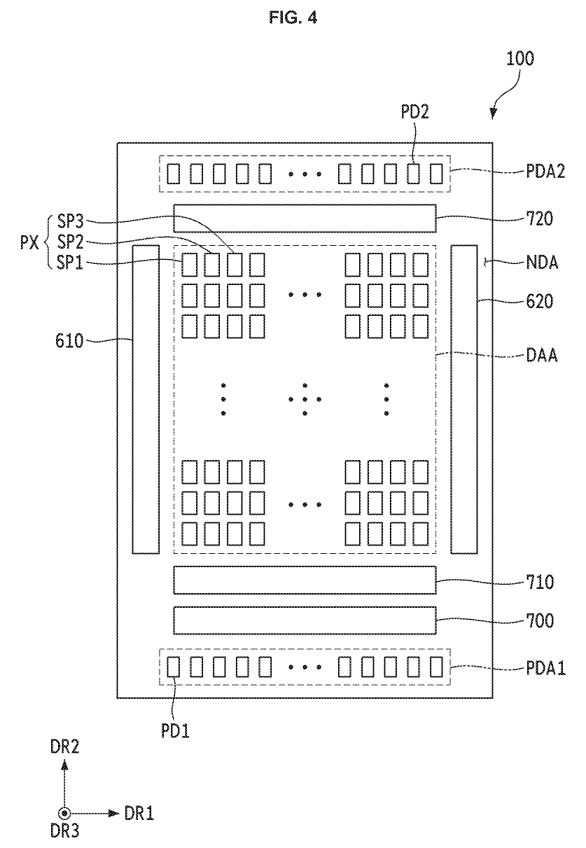

The circuit board 300 may be electrically connected to a plurality of first pads PD1 (see, e.g., FIG. 4) in a first pad portion PDA1 (see, e.g., FIG. 4) of the display panel 100 by using a conductive adhesive member such as an anisotropic conductive film. The circuit board 300 may be a flexible printed circuit board or a flexible film. Although the circuit board 300 is unfolded in FIG. 1, it may also be bent. In such embodiments, one end of the circuit board 300 may be placed on the back surface of the display panel 100 and/or a back surface of the heat dissipation layer 200. The other end of the circuit board 300 may be connected to the first pads PD1 (see, e.g., FIG. 4) of the first pad portion PDA1 (see, e.g., FIG. 4) of the display panel 100 by using a conductive adhesive member. The one end of the circuit board 300 may be an end opposite the other end of the circuit board 300.

The timing control circuit 400 may receive digital video data and timing signals from the outside. The timing control circuit 400 may generate the scan timing control signal SCS, the emission timing control signal ECS, and the data timing control signal DCS for controlling the display panel 100 according to the timing signals. The timing control circuit 400 may output the scan timing control signal SCS to the scan driver 610 and the emission timing control signal ECS to the emission driver 620. The timing control circuit 400 may output the digital video data DATA and the data timing control signal DCS to the data driver 700.

The power supply circuit 500 may generate a plurality of panel driving voltages according to a power supply voltage received from the outside. For example, the power supply circuit 500 may generate a first driving voltage VSS, a second driving voltage VDD and a third driving voltage VINT and supply them to the display panel 100. The first driving voltage VSS, the second driving voltage VDD, and the third driving voltage VINT will be described in more detail with reference to FIG. 3.

Each of the timing control circuit 400 and the power supply circuit 500 may be formed as an integrated circuit and attached to a surface of the circuit board 300. In such embodiments, the scan timing control signal SCS, the emission timing control signal ECS, the digital video data DATA, and the data timing control signal DCS of the timing control circuit 400 may be supplied to the display panel 100 through the circuit board 300. In one or more embodiments, the first driving voltage VSS, the second driving voltage VDD, and the third driving voltage VINT of the power supply circuit 500 may be supplied to the display panel 100 through the circuit board 300.

Alternatively, the timing control circuit 400 and the power supply circuit 500 may be located in the non-display area NDA of the display panel 100, like the scan driver 610, the emission driver 620, and the data driver 700. In such embodiments, the timing control circuit 400 may include a plurality of timing transistors, and the power supply circuit 500 may include a plurality of power transistors. The timing transistors and the power transistors may be formed through a semiconductor process and may be formed in the semiconductor substrate SSUB (see, e.g., FIG. 7). For example, the timing transistors and the power transistors may be formed as CMOS transistors, but the present disclosure is not limited thereto. Each of the timing control circuit 400 and the power supply circuit 500 may be located between the data driver 700 and the first pad portion PDA1 (see, e.g., FIG. 4).

FIG. 3 is an equivalent circuit diagram of a first subpixel SP1 according to one or more embodiments of the present disclosure.

Referring to FIG. 3, the first subpixel SP1 may be connected to a write scan line GWL, a control scan line GCL, a bias scan line GBL, a first emission control line EL1, a second emission control line EL2, and a data line DL. In addition, the first subpixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low-potential voltage line, the second driving voltage line VDL may be a high-potential voltage line, and the third driving voltage line VIL may be an initialization voltage line. Here, the first driving voltage VSS may be lower than the third driving voltage VINT. The second driving voltage VDD may be higher than the third driving voltage VINT.

The first subpixel SP1 includes a plurality of transistors T1 through T6, a light emitting element LE, a first capacitor CP1, and a second capacitor CP2.

The light emitting element LE is to emit light according to a driving current Ids flowing through a channel of a first transistor T1. The amount of light emitted from the light emitting element LE may be proportional to the driving current. The light emitting element LE may be located between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode, and the second electrode of the light emitting element LE may be a cathode. The light emitting element LE may be an organic light emitting diode including a first electrode, a second electrode, and an organic light emitting layer located between the first electrode and the second electrode. However, the present disclosure is not limited thereto. For example, the light emitting element LE may be an inorganic light emitting element including a first electrode, a second electrode, and an inorganic semiconductor located between the first electrode and the second electrode. In such embodiments, the light emitting element LE may be a micro light emitting diode.

The first transistor T1 may be a driving transistor that controls a source-drain current (hereinafter, referred to as a “driving current”) flowing between a source electrode and a drain electrode according to a voltage applied to a gate electrode. The first transistor T1 includes the gate electrode connected to a first node N1, the source electrode connected to a drain electrode of a sixth transistor T6, and the drain electrode connected to a second node N2.

A second transistor T2 may be located between one electrode of the first capacitor CP1 and the data line DL. The second transistor T2 is turned on by a write scan signal of the write scan line GWL and connects the electrode of the first capacitor CP1 to the data line DL. Accordingly, a data voltage of the data line DL may be applied to the electrode of the first capacitor CP1. The second transistor T2 includes a gate electrode connected to the write scan line GWL, a source electrode connected to the data line DL, and a drain electrode connected to the electrode of the first capacitor CP1.

A third transistor T3 may be located between the first node N1 and the second node N2. The third transistor T3 is turned on by a write control signal of the write control line GCL and connects the first node N1 to the second node N2. Accordingly, when the gate electrode and source electrode of the first transistor T1 are connected, the first transistor T1 may operate as a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 and connects the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and the drain electrode connected to the third node N3.

A fifth transistor T5 may be located between the third node N3 and the third driving voltage line VIL. The fifth transistor T5 is turned on by a bias scan signal of the bias scan line GBL and connects the third node N3 to the third driving voltage line VIL. Accordingly, the third driving voltage VINT of the third driving voltage line VIL may be applied to the first electrode of the light emitting element LE. The fifth transistor T5 includes a gate electrode connected to the bias scan line GBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 is turned on by a second emission control signal of the second emission control line EL2 and connects the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and the drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a contact point between the gate electrode of the first transistor T1, the drain electrode of the third transistor T3, the other electrode of the first capacitor CP1, and the one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first through sixth transistors T1 through T6 may be a metal-oxide-semiconductor field effect transistor (MOSFET). For example, each of the first through sixth transistors T1 through T6 may be a P-type MOSFET. However, the present disclosure is not limited thereto. Each of the first through sixth transistors T1 through T6 may also be an N-type MOSFET. Alternatively, some of the first through sixth transistors T1 through T6 may be P-type MOSFETs, and the other transistors may be N-type MOSFETs.

In FIG. 3, the first subpixel SP1 includes six transistors T1 through T6 and two capacitors CP1 and CP2. However, it should be noted that the equivalent circuit diagram of the first subpixel SP1 is not limited to that illustrated in FIG. 3. For example, the number of transistors and the number of capacitors in the first subpixel SP1 are not limited to those illustrated in FIG. 3.

In addition, an equivalent circuit diagram of a second subpixel SP2 and an equivalent circuit diagram of a third subpixel SP3 may be substantially the same as the equivalent circuit diagram of the first subpixel SP1 described with reference to FIG. 3. Therefore, the equivalent circuit diagram of the second subpixel SP2 and the equivalent circuit diagram of the third subpixel SP3 may not be described in the present specification.

FIG. 4 is a layout view of a display panel 100 according to one or more embodiments of the present disclosure.

Referring to FIG. 4, a display area DAA of the display panel 100 according to one or more embodiments includes a plurality of pixels PX arranged in a matrix form. A non-display area NDA of the display panel 100 according to one or more embodiments includes a scan driver 610, an emission driver 620, a data driver 700, a first distribution circuit 710, a second distribution circuit 720, a first pad portion PDA1, and a second pad portion PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. That is, the scan driver 610 may be located on a left side of the display area DAA, and the emission driver 620 may be located on a right side of the display area DAA. However, the present disclosure is not limited thereto, and the scan driver 610 and the emission driver 620 may also be located on either the first or second side of the display area DAA.

The first pad portion PDA1 may include a plurality of first pads PD1 connected to pads or bumps of the circuit board 300 through a conductive adhesive member. The first pad portion PDA1 may be located on a third side of the display area DAA. For example, the first pad portion PDA1 may be located on one side of the display area DAA in the second direction DR2. The first pad portion PDA1 may be located outside the data driver 700 in the second direction DR2. That is, the first pad portion PDA1 may be located closer to an edge of the display panel 100 than the data driver 700.

The second pad portion PDA2 may include a plurality of second pads PD2 corresponding to test pads for testing whether the display panel 100 operates normally. The second pads PD2 may be connected to a jig or a probe pin during a test process or may be connected to a test circuit board. The test circuit board may be a rigid printed circuit board or a flexible printed circuit board.

The second pad portion PDA2 may be located on a fourth side of the display area DAA. For example, the second pad portion PDA2 may be located on the other side of the display area DAA in the second direction DR2. The second pad portion PDA2 may be located outside the second distribution circuit 720 in the second direction DR2. That is, the second pad portion PDA2 may be located closer to an edge of the display panel 100 than the second distribution circuit 720.

The first distribution circuit 710 may distribute data voltages received through the first pad portion PDA1 to a plurality of data lines DL. For example, the first distribution circuit 710 may distribute data voltages received through one first pad PD1 of the first pad portion PDA1 to P (P is a positive integer of 2 or more) data lines DL. Therefore, the number of first pads PD1 can be reduced. The first distribution circuit 710 may be located on the third side of the display area DAA of the display panel 100. For example, the first distribution circuit 710 may be located on one side of the display area DAA in the second direction DR2. That is, the first distribution circuit 710 may be located on a lower side of the display area DAA.

The second distribution circuit 720 distributes signals received through the second pad portion PDA2 to the scan driver 610, the emission driver 620, and the data lines DL. The second pad portion PDA2 and the second distribution circuit 720 may be elements for testing the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2. That is, the second distribution circuit 720 may be located on an upper side of the display area DAA.

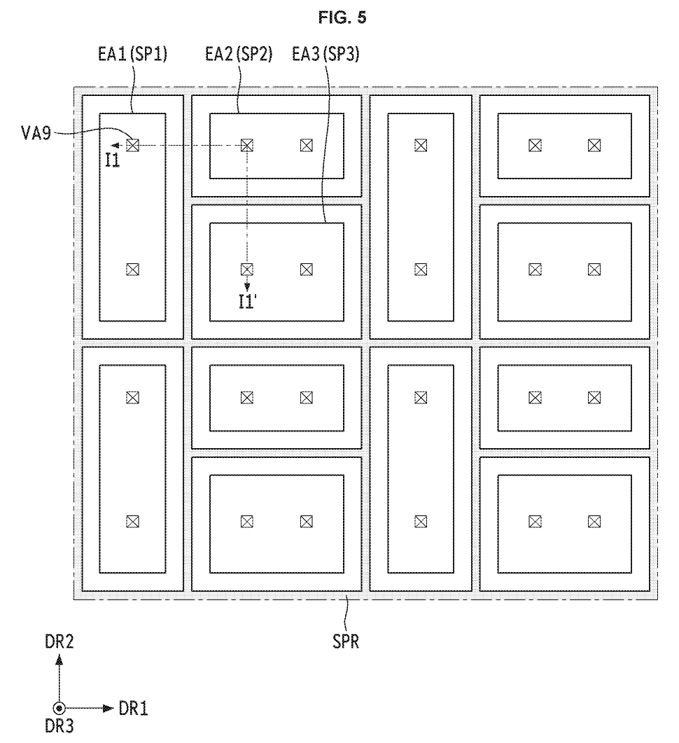

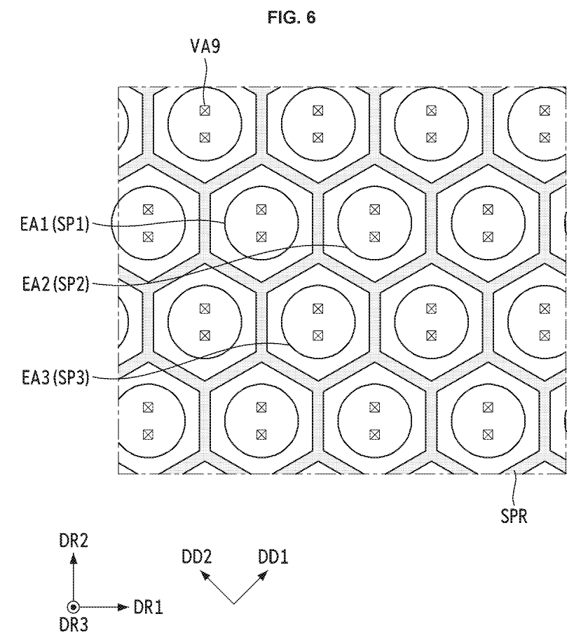

FIGS. 5 and 6 are each a layout view of the display area DAA of FIG. 4, according to one or more embodiments of the present disclosure.

Referring to FIGS. 5 and 6, each of a plurality of pixels PX includes a first emission area EA1 which is an emission area of a first subpixel SP1, a second emission area EA2 which is an emission area of a second subpixel SP2, and a third emission area EA3 which is an emission area of a third subpixel SP3.

Each of the first emission area EA1, the second emission area EA2, and the third emission area EA3 may have a polygonal, circular, oval, or irregular planar shape.

As shown, for example, in FIG. 5, maximum length of the first emission area EA1 in the first direction DR1 may be smaller than a maximum length of the second emission area EA2 in the first direction DR1 and a maximum length of the third emission area EA3 in the first direction DR1. The maximum length of the second emission area EA2 in the first direction DR1 may be substantially equal to the maximum length of the third emission area EA3 in the first direction DR1.

A maximum length of the first emission area EA1 in the second direction DR2 may be greater than a maximum length of the second emission area EA2 in the second direction DR2 and a maximum length of the third emission area EA3 in the second direction DR2. The maximum length of the second emission area EA2 in the second direction DR2 may be greater than the maximum length of the third emission area EA3 in the second direction DR2. In some embodiments, the maximum length of the first emission area EA1 in the second direction DR2 may be smaller than the maximum length of the second emission area EA2 in the second direction DR2.

The first emission area EA1, the second emission area EA2, and the third emission area EA3 may have a quadrangular shape as illustrated in FIG. 5 or a circular shape as illustrated in FIG. 6. However, the present disclosure is not limited thereto. The first emission area EA1, the second emission area EA2, and the third emission area EA3 may also have a polygonal planar shape other than a hexagonal shape or an oval or irregular planar shape.

As illustrated in FIG. 5, in each of the pixels PX, the first emission area EA1 and the second emission area EA2 may neighbor each other in the first direction DR1. In addition, the first emission area EA1 and the third emission area EA3 may neighbor each other in the first direction DR1. In addition, the second emission area EA2 and the third emission area EA3 may neighbor each other in the second direction DR2. The area of the first emission area EA1, the area of the second emission area EA2, and the area of the third emission area EA3 may be different.

Alternatively, as illustrated in FIG. 6, the first emission area EA1 and the second emission area EA2 may neighbor each other in the first direction DR1. However, the second emission area EA2 and the third emission area EA3 may neighbor each other in a first diagonal direction DD1, and the first emission area EA1 and the third emission area EA3 may neighbor each other in a second diagonal direction DD2. The first diagonal direction DD1 may be a direction between the first direction DR1 and the second direction DR2 and a direction inclined at 45 degrees with respect to the first direction DR1 and the second direction DR2. The second diagonal direction DD2 may be a direction orthogonal to the first diagonal direction DD1.

The first subpixel SP1 may output first light that has passed through a first color filter CF1 (see, e.g., FIG. 7) among light emitted from the first emission area EA1, the second subpixel SP2 may output second light that has passed through a second color filter CF2 (see, e.g., FIG. 7) among light emitted from the second emission area EA2, and the third subpixel SP3 may output third light that has passed through a third color filter CF3 (see, e.g., FIG. 7) among light emitted from the third emission area EA3.

The first light, the second light, and the third light may be light of different wavelength bands. For example, any one of the first light, the second light and the third light may be light in a blue wavelength band, another may be light in a green wavelength band, and the other may be light in a red wavelength band. Here, the blue wavelength band may indicate that a main peak wavelength of light is included in a wavelength band of about 370 to 460 nm, the green wavelength band may indicate that a main peak wavelength of light is included in a wavelength band of about 480 to 560 nm, and the red wavelength band may indicate that a main peak wavelength of light is included in a wavelength band of about 600 to 750 nm.

Although each of the pixels PX includes three emission areas EA1 through EA3 in FIGS. 5 and 6, the present disclosure is not limited thereto. That is, for example, each of the pixels PX may include four emission areas.

In addition, the arrangement of the emission areas of the pixels PX is not limited to those illustrated in FIGS. 5 and 6. For example, the emission areas of the pixels PX may also be arranged in a stripe structure in which emission areas are arranged in the first direction DR1, in a PenTile® structure (for example, an RGBG matrix, an RGBG structure, or RGBG matrix structure), a diamond structures (Diamond Pixel^{®}) (e.g., containing red, blue, and green (RGB) light emitting regions arranged in the shape of diamonds), or in a hexagonal structure in which emission areas having a circle planar shape are arranged as illustrated in FIG. 6. PENTILE^{®} and DIAMOND PIXEL^{®} are duly registered trademarks of Samsung Display Co., Ltd.

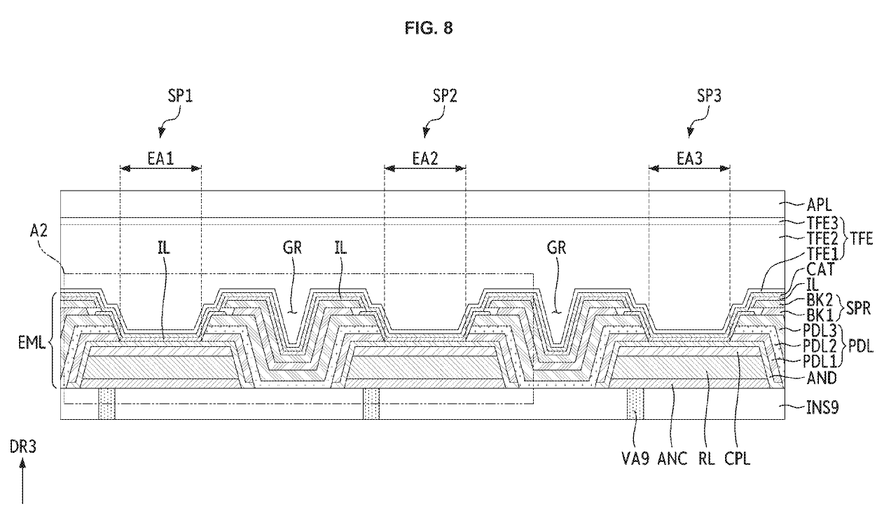

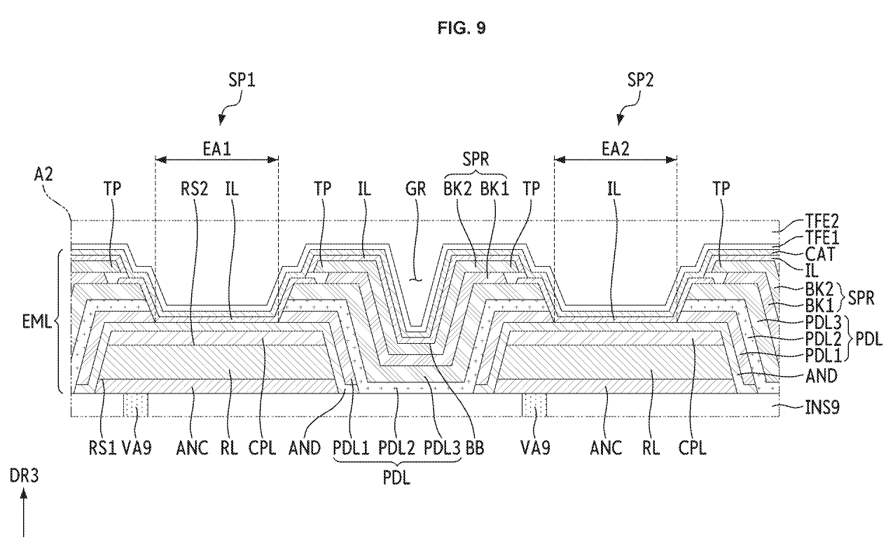

FIG. 7 is a cross-sectional view of the display panel 100 taken along the line I1-I1’ of FIG. 5, according to one or more embodiments of the present disclosure. FIG. 8 is a detailed cross-sectional view of the area A1 of FIG. 7, according to one or more embodiments of the present disclosure. FIG. 9 is a detailed cross-sectional view of the area A2 of FIG. 8, according to one or more embodiments of the present disclosure.

Referring to FIGS. 7 through 9, the display panel 100 includes a semiconductor backplane SBP, a light emitting element backplane EBP, a display element layer EML, an encapsulation layer TFE, an optical layer OPL including a cover layer CVL, and a polarizer POL.

The semiconductor backplane SBP includes a semiconductor substrate SSUB including a plurality of pixel transistors PTR, a plurality of semiconductor insulating layers covering the pixel transistors PTR, and a plurality of contact terminals CTE electrically connected to the pixel transistors PTR. The pixel transistors PTR may be the first through sixth transistors T1 through T6 described with reference to FIG. 4.

The semiconductor substrate SSUB may be a silicon substrate, a germanium substrate, or a silicon-germanium substrate. The semiconductor substrate SSUB may be a substrate doped with first-type impurities. A plurality of well areas WA may be located in an upper surface of the semiconductor substrate SSUB. The well areas WA may be areas doped with second-type impurities. The second-type impurities may be different from the first-type impurities described above. For example, when the first-type impurities are p-type impurities, the second-type impurities may be n-type impurities. Alternatively, when the first-type impurities are n-type impurities, the second-type impurities may be p-type impurities.

Each of the well areas WA includes a source area SA corresponding to a source electrode of a pixel transistor PTR, a drain area DA corresponding to a drain electrode of the pixel transistor PTR, and a channel area CH located between the source area SA and the drain area DA.

A bottom insulating layer BINS may be located between a gate electrode GE and each well area WA. A side insulating layer SINS may be located on side surfaces of the gate electrode GE. The side insulating layer SINS may be located on the bottom insulating layer BINS.

Each of the source area SA and the drain area DA may be an area doped with the first-type impurities. The gate electrode GE of each pixel transistor PTR may overlap a well area WA in the third direction DR3 which is a thickness direction of the semiconductor substrate SSUB. The channel area CH may overlap the gate electrode GE in the third direction DR3. The source area SA may be located on one side of the gate electrode GE, and the drain area DA may be located on the other side of the gate electrode GE.

Each of the well areas WA further includes a first lightly doped impurity area LDD1 located between the channel area CH and the source area SA and a second lightly doped impurity area LDD2 located between the channel area CH and the drain area DA. The first lightly doped impurity area LDD1 may be an area having a lower impurity concentration than the source area SA due to the bottom insulating layer BINS. The second lightly doped impurity area LDD2 may be an area having a lower impurity concentration than the drain area DA due to the bottom insulating layer BINS. A distance between the source area SA and the drain area DA may be increased by the first lightly doped impurity area LDD1 and the second lightly doped impurity area LDD2. Accordingly, a length of the channel area CH of each pixel transistor PTR may increase, thereby preventing punch-through and hot carrier phenomena caused by a short channel.

A first semiconductor insulating layer SINS1 may be located on the semiconductor substrate SSUB. The first semiconductor insulating layer SINS1 may include a silicon carbon nitride (SiCN) or silicon oxide (SiOₓ)-based inorganic layer, but the present disclosure is not limited thereto.

A second semiconductor insulating layer SINS2 may be located on the first semiconductor insulating layer SINS1. The second semiconductor insulating layer SINS2 may include a silicon oxide (SiOₓ)-based inorganic layer, but the present disclosure is not limited thereto.

The contact terminals CTE may be located on the second semiconductor insulating layer SINS2. Each of the contact terminals CTE may be connected to any one of the gate electrode GE, the source area SA, and/or the drain area DA of a pixel transistor PTR through a hole penetrating the first semiconductor insulating layer SINS1 and the second semiconductor insulating layer SINS2. The contact terminals CTE may include any one of copper (Cu), aluminum (Al), tungsten (W), molybdenum (Mo), chromium (Cr), gold (Au), titanium (Ti), nickel (Ni) and/or neodymium (Nd) or may include an alloy including any one or more of the same.

A third semiconductor insulating layer SINS3 may be located on side surfaces of each of the contact terminals CTE. An upper surface of each of the contact terminals CTE may be exposed without being covered by the third semiconductor insulating layer SINS3. The third semiconductor insulating layer SINS3 may include a silicon oxide (SiOₓ)-based inorganic layer, but the present disclosure is not limited thereto.

The semiconductor substrate SSUB can be replaced with a glass substrate or a polymer resin substrate such as polyimide. In such embodiments, thin-film transistors may be located on the glass substrate or the polymer resin substrate. The glass substrate may be a rigid substrate that is not bent, and the polymer resin substrate may be a flexible substrate that can be bent or curved.

The light emitting element backplane EBP includes a plurality of conductive layers ML1 through ML8, a plurality of via electrodes VA1 through VA9, and a plurality of insulating layers INS1 through INS9. In one or more embodiments, the light emitting element backplane EBP may include a plurality of insulating layers INS1 through INS9 located between first through eighth conductive layers ML1 through ML8.

The first through eighth conductive layers ML1 through ML8 implement the circuit of the first subpixel SP1 illustrated in FIG. 3 by connecting the contact terminals CTE exposed in the semiconductor backplane SBP. For example, the first through sixth transistors T1 through T6 are simply formed in the semiconductor backplane SBP, and the connection of the first through sixth transistors T1 through T6 and the first and second capacitors CP1 and CP2 are achieved through the first through eighth conductive layers ML1 through ML8. In addition, the connection between a drain area corresponding to the drain electrode of the fourth transistor T4, a source area corresponding to the source electrode of the fifth transistor T5, and the first electrode AND of the light emitting element LE is achieved through the first through eighth conductive layers ML1 through ML8.

A first insulating layer INS1 may be located on the semiconductor backplane SBP. First via electrodes VA1 may penetrate the first insulating layer INS1 and may be respectively connected to the contact terminals CTE exposed in the semiconductor backplane SBP. The first conductive layers ML1 may be located on the first insulating layer INS1 and may be connected to the first via electrodes VA1, respectively.

A second insulating layer INS2 may be located on the first insulating layer INS1 and the first conductive layers ML1. Second via electrodes VA2 may penetrate the second insulating layer INS2 and may be connected to the exposed first conductive layers ML1, respectively. The second conductive layers ML2 may be located on the second insulating layer INS2 and may be connected to the second via electrodes VA2, respectively.

A third insulating layer INS3 may be located on the second insulating layer INS2 and the second conductive layers ML2. Third via electrodes VA3 may penetrate the third insulating layer INS3 and may be connected to the exposed second conductive layers ML2, respectively. The third conductive layers ML3 may be located on the third insulating layer INS3 and may be connected to the third via electrodes VA3, respectively.

A fourth insulating layer INS4 may be located on the third insulating layer INS3 and the third conductive layers ML3. Fourth via electrodes VA4 may penetrate the fourth insulating layer INS4 and may be connected to the exposed third conductive layers ML3, respectively. The fourth conductive layers ML4 may be located on the fourth insulating layer INS4 and may be connected to the fourth via electrodes VA4, respectively.

A fifth insulating layer INS5 may be located on the fourth insulating layer INS4 and the fourth conductive layers ML4. Fifth via electrodes VA5 may penetrate the fifth insulating layer INS5 and may be connected to the exposed fourth conductive layers ML4, respectively. The fifth conductive layers ML5 may be located on the fifth insulating layer INS5 and may be connected to the fifth via electrodes VA5, respectively.

A sixth insulating layer INS6 may be located on the fifth insulating layer INS5 and the fifth conductive layers ML5. Sixth via electrodes VA6 may penetrate the sixth insulating layer INS6 and may be connected to the exposed fifth conductive layers ML5, respectively. The sixth conductive layers ML6 may be located on the sixth insulating layer INS6 and may be connected to the sixth via electrodes VA6, respectively.

A seventh insulating layer INS7 may be located on the sixth insulating layer INS6 and the sixth conductive layers ML6. Each of seventh via electrodes VA7 may penetrate the seventh insulating layer INS7 and may be connected to an exposed sixth conductive layer ML6. The seventh conductive layers ML7 may be located on the seventh insulating layer INS7 and may be connected to the seventh via electrodes VA7, respectively.

An eighth insulating layer INS8 may be located on the seventh insulating layer INS7 and the seventh conductive layers ML7. Eighth via electrodes VA8 may penetrate the eighth insulating layer INS8 and may be connected to the exposed seventh conductive layers ML7, respectively. The eighth conductive layers ML8 may be located on the eighth insulating layer INS8 and may be connected to the eighth via electrodes VA8, respectively.

The first through eighth conductive layers ML1 through ML8 and the first through eighth via electrodes VA1 through VA8 may include substantially the same material. The first through eighth conductive layers ML1 through ML8 and the first through eighth via electrodes VA1 through VA8 may include any one of copper (Cu), aluminum (Al), tungsten (W), molybdenum (Mo), chromium (Cr), gold (Au), titanium (Ti), nickel (Ni) and neodymium (Nd) or may include an alloy including any one or more of the same. The first through eighth via electrodes VA1 through VA8 may include substantially the same material. The first through eighth insulating layers INS1 through INS8 may include a silicon oxide (SiOₓ)-based inorganic layer, but the present disclosure is not limited thereto.

A thickness of the first conductive layers ML1, a thickness of the second conductive layers ML2, a thickness of the third conductive layers ML3, a thickness of the fourth conductive layers ML4, a thickness of the fifth conductive layers ML5, and a thickness of the sixth conductive layers ML6 may each be greater than each of a thickness of the first via electrodes VA1, a thickness of the second via electrodes VA2, a thickness of the third via electrodes VA3, a thickness of the fourth via electrodes VA4, a thickness of the fifth via electrodes VA5, and a thickness of the sixth via electrodes VA6. The thickness of the second conductive layers ML2, the thickness of the third conductive layers ML3, the thickness of the fourth conductive layers ML4, the thickness of the fifth conductive layers ML5, and the thickness of the sixth conductive layers ML6 may each be greater than the thickness of the first conductive layers ML1. The thickness of the second conductive layers ML2, the thickness of the third conductive layers ML3, the thickness of the fourth conductive layers ML4, the thickness of the fifth conductive layers ML5, and the thickness of the sixth conductive layers ML6 may be substantially the same. For example, the thickness of the first conductive layers ML1 may be about 1,360 Å, and the thickness of the second conductive layers ML2, the thickness of the third conductive layers ML3, the thickness of the fourth conductive layers ML4, the thickness of the fifth conductive layers ML5, and the thickness of the sixth conductive layers ML6 may each be about 1,440 Å. In addition, the thickness of the first via electrodes VA1, the thickness of the second via electrodes VA2, the thickness of the third via electrodes VA3, the thickness of the fourth via electrodes VA4, the thickness of the fifth via electrodes VA5, and the thickness of the sixth via electrodes VA6 may each be about 1,150 Å.

A thickness of the seventh conductive layers ML7 and a thickness of the eighth conductive layers ML8 may each be greater than each of the thickness of the first conductive layers ML1, the thickness of the second conductive layers ML2, the thickness of the third conductive layers ML3, the thickness of the fourth conductive layers ML4, the thickness of the fifth conductive layers ML5, and the thickness of the sixth conductive layer ML6. The thickness of the seventh conductive layers ML7 and the thickness of the eighth conductive layers ML8 may each be greater than each of a thickness of the seventh via electrodes VA7 and a thickness of the eighth via electrodes VA8. The thickness of the seventh via electrodes VA7 and the thickness of the eighth via electrodes VA8 may each be greater than each of the thickness of the first via electrodes VA1, the thickness of the second via electrodes VA2, the thickness of the third via electrodes VA3, the thickness of the fourth via electrodes VA4, the thickness of the fifth via electrodes VA5, and the thickness of the sixth via electrodes VA6. The thickness of the seventh conductive layers ML7 and the thickness of the eighth conductive layers ML8 may be substantially the same. For example, the thickness of the seventh conductive layers ML7 and the thickness of the eighth conductive layers ML8 may each be about 9,000 Å. The thickness of the seventh via electrodes VA7 and the thickness of the eighth via electrodes VA8 may each be about 6,000 Å.

A ninth insulating layer INS9 may be located on the eighth insulating layer INS8 and the eighth conductive layers ML8. The ninth insulating layer INS9 may include a silicon oxide (SiOₓ)-based inorganic layer, but the present disclosure is not limited thereto.

Ninth via electrodes VA9 may penetrate the ninth insulating layer INS9 and may be connected to the exposed eighth conductive layers ML8, respectively. The ninth via electrodes VA9 may include any one of copper (Cu), aluminum (Al), tungsten (W), molybdenum (Mo), chromium (Cr), gold (Au), titanium (Ti), nickel (Ni) and/or neodymium (Nd) or may include an alloy including any one or more of the same. A thickness of the ninth via electrodes VA9 may be about 16,500 Å.

The display element layer EML may be located on the light emitting element backplane EBP. The display element layer EML may include a plurality of connection electrodes ANC, a plurality of reflective electrodes RL, capping layers CPL, a pixel defining layer PDL, a plurality of first electrodes AND, a light emitting stack IL, a second electrode CAT, and a separator SPR.

In addition, the display element layer EML may include a first emission area EA1, a second emission area EA2, and a third emission area EA3. Each of the first emission area EA1, the second emission area EA2, and the third emission area EA3 may be an area where a first electrode AND, the light emitting stack IL, and the second electrode CAT are sequentially stacked. Each of the first emission area EA1, the second emission area EA2, and the third emission area EA3 may be an area where a light emitting element LE including the first electrode AND, the light emitting stack IL, and the second electrode CAT is located. Each of the first emission area EA1, the second emission area EA2, and the third emission area EA3 may be defined by the pixel defining layer PDL.

The connection electrodes ANC may be located on the ninth insulating layer INS9. For example, the connection electrodes ANC may be located on the ninth insulating layer INS9 such that they are connected to the ninth via electrodes VA9, respectively. The connection electrodes ANC may include titanium nitride (TiN) or a transparent conductive oxide. For example, the transparent conductive oxide may be indium tin oxide (ITO) or indium zinc oxide (IZO), but the present disclosure is not limited thereto.

The reflective electrodes RL may be located on the connection electrodes ANC, respectively. For example, the reflective electrodes RL may be located between the connection electrodes ANC and capping layers CPL, respectively. Each of the reflective electrodes RL may include any one of copper (Cu), aluminum (Al), silver (Ag), tungsten (W), molybdenum (Mo), chromium (Cr), gold (Au), titanium (Ti), nickel (Ni) and/or neodymium (Nd) or may include an alloy including any one or more of the same.

For example, each of the reflective electrodes RL may include aluminum (Al) or silver (Ag).

The capping layers CPL may be located on the reflective electrodes RL, respectively. For example, the capping layers CPL may be located on upper surfaces of the reflective electrodes RL. Thicknesses TT of the capping layers CPL in different subpixels may be equal to each other. For example, a thickness TT of a capping layer CPL overlapping the first emission area EA1 of a first subpixel SP1, a thickness of a capping layer CPL overlapping the second emission area EA2 of a second subpixel SP2, and a thickness of a capping layer CPL overlapping the third emission area EA3 of a third subpixel SP3 may be equal to each other. Each of the capping layers CPL may include a silicon oxide (SiOₓ)-based inorganic layer, but the present disclosure is not limited thereto.

Each of light emitting elements LE may include a first electrode AND, the light emitting stack IL, and the second electrode CAT.

The first electrode AND may be located on a capping layer CPL. For example, the first electrode AND may be located on an upper surface of the capping layer CPL, side surfaces of the capping layer CPL, side surfaces of a reflective electrode RL, side surfaces of a connection electrode ANC, and an upper surface of the ninth insulating layer INS9. The first electrode AND may contact (or directly contact) the upper surface of the capping layer CPL, the side surfaces of the capping layer CPL, the side surfaces of the reflective electrode RL, the side surfaces of the connection electrode ANC, and the upper surface of the ninth insulating layer INS9. Since side surfaces of the first electrode AND and the side surfaces of the connection electrode ANC contact each other, the first electrode AND and the connection electrode ANC may be electrically connected to each other.

A thickness of the first electrode AND on the side surfaces of the capping layer CPL may be different from a thickness of the first electrode AND on the upper surface of the capping layer CPL. For example, the thickness of the first electrode AND on the side surfaces of the capping layer CPL may be smaller than the thickness of the first electrode AND on the upper surface of the capping layer CPL. Specifically, the thickness of the first electrode AND overlapping the side surfaces of the capping layer CPL may be smaller than the thickness of the first electrode AND overlapping the upper surface of the capping layer CPL.

The first electrode AND of each of the light emitting elements LE may be connected to the drain area DA or the source area SA of a pixel transistor PTR through the connection electrode ANC, the first through ninth via electrodes VA1 through VA9, the first through eighth conductive layers ML1 through ML8, and a contact terminal CTE.

The first electrode AND of each of the light emitting elements LE may include any one of copper (Cu), aluminum (Al), tungsten (W), molybdenum (Mo), chromium (Cr), gold (Au), titanium (Ti), nickel (Ni) and/or neodymium (Nd) or may include an alloy including any one or more of the same. For example, the first electrode AND of each of the light emitting elements LE may be titanium nitride (TiN).

The pixel defining layer PDL may define the first through third emission areas EA1 through EA3. The pixel defining layer PDL may be located between adjacent subpixels SP1 through SP3 (e.g., adjacent first electrodes AND of adjacent subpixels of subpixels SP1 to SP3). The pixel defining layer PDL may be located on edges of the first electrode AND of each of the light emitting elements LE and on the ninth insulating layer INS9. The pixel defining layer PDL may cover edges of an upper portion of the first electrode AND of each of the light emitting elements LE. The pixel defining layer PDL may contact (or directly contact) the first electrode AND. The pixel defining layer PDL may be located on the upper portion of the first electrode AND and a side portion of the first electrode AND.

The pixel defining layer PDL may have a groove GR which is sunken toward (e.g., is along the third direction in the direction of) the semiconductor substrate SSUB as illustrated, for example, in FIGS. 8 and 9. For example, the pixel defining layer PDL may have the groove GR between adjacent subpixels SP1 through SP3 (e.g., between adjacent first electrodes AND of adjacent subpixels of subpixels SP1 to SP3). In a plan view, the groove GR may surround each of the subpixels SP1 through SP3. For example, in a plan view as illustrated in FIGS. 5 and 6, for example, the groove GR may have substantially the same shape as the separator SPR. The groove GR may be located at a center of the separator SPR.

The pixel defining layer PDL may include a first pixel defining layer PDL1, a second pixel defining layer PDL2, and a third pixel defining layer PDL3.

The first pixel defining layer PDL1 may be located on the edges of the upper portion of the first electrode AND and the side portion of the first electrode AND. The first pixel defining layer PDL may have a discontinuous cross-section between adjacent subpixels SP1 through SP3 (e.g., between adjacent first electrodes AND of adjacent subpixels of subpixels SP1 to SP3). In other words, the first pixel defining layer PDL1 may have a broken cross-section between adjacent subpixels SP1 through SP3 (e.g., between adjacent first electrodes AND of adjacent subpixels of subpixels SP1 to SP3). The first pixel defining layer PDL1 may not contact the ninth insulating layer INS9. The first pixel defining layer PDL1 may include a material including silicon oxide (SiOₓ, e.g., SiO2).

The second pixel defining layer PDL2 may be located on the first pixel defining layer PDL1 and the ninth insulating layer INS9. For example, the second pixel defining layer PDL2 may be located on an upper portion of the first pixel defining layer PDL1 and a side portion of the first pixel defining layer PDL1 and may also be located on the ninth insulating layer INS9. The second pixel defining layer PDL2 may be located between the first pixel defining layer PDL1 and the third pixel defining layer PDL3. The second pixel defining layer PDL2 may have a continuous cross-section between adjacent subpixels SP1 through SP3 (e.g., between adjacent first electrodes AND of adjacent subpixels of subpixels SP1 to SP3). A lower portion of the second pixel defining layer PDL2 may contact (or directly contact) the ninth insulating layer INS9. The lower portion of the second pixel defining layer PDL2 may be located between respective ends (e.g., etched surfaces) of adjacent first electrodes AND. The lower portion of the second pixel defining layer PDL2 may contact (or directly contact) the respective ends (e.g., etched surfaces) of adjacent first electrodes AND. The second pixel defining layer PDL2 may include a material including silicon nitride (SiNₓ).

The third pixel defining layer PDL3 may be located on the second pixel defining layer PDL2. For example, the third pixel defining layer PDL3 may be located on an upper portion of the second pixel defining layer PDL2, a side portion of the second pixel defining layer PDL2, and the lower portion of the second pixel defining layer PDL2. The third pixel defining layer PDL3 may have a continuous cross-section between adjacent subpixels SP1 through SP3 (e.g., between adjacent first electrodes AND of adjacent subpixels of subpixels SP1 to SP3). The third pixel defining layer PDL3 may include a material including silicon oxide (SiOₓ, e.g., SiO₂).

The first emission area EA1 may be defined as an area in the first subpixel SP1 where a first electrode AND, the light emitting stack IL, and the second electrode CAT are sequentially stacked to emit light. The second emission area EA2 may be defined as an area in the second subpixel SP2 where a first electrode AND, the light emitting stack IL, and the second electrode CAT are sequentially stacked to emit light. The third emission area EA3 may be defined as an area in the third subpixel SP3 where a first electrode AND, the light emitting stack IL, and the second electrode CAT are sequentially stacked to emit light.

The separator SPR may be located on the pixel defining layer PDL. In a plan view, as illustrated in FIGS. 5 and 6, the separator SPR may be shaped like a closed curve or polygon surrounding each of the emission areas EA1 through EA3. The separator SPR may be located on the pixel defining layer PDL to surround each of the emission areas EA1 through EA3. The separator SPR may have the groove GR which is sunken toward (e.g., is along the third direction in the direction of) the semiconductor substrate SSUB as illustrated in FIGS. 8 and 9. For example, the separator SPR may have the groove GR between adjacent subpixels SP1 through SP3 (e.g., between adjacent first electrodes AND of adjacent subpixels of subpixels SP1 to SP3). In a plan view, the groove GR may surround each of the subpixels SP1 through SP3. For example, in a plan view, as illustrated in FIGS. 5 and 6, the groove GR may have substantially the same shape as the separator SPR. The groove GR may be located at the center of the separator SPR. The separator SPR may separate the light emitting stack IL. To this end, according to one or more embodiments, the separator SPR may include a first bank BK1 and a second bank BK2 having different areas.

A bottom surface BB of the groove GR (e.g., the groove GR of a structure including the separator SPR and the pixel defining layer PDL) may be located at a height between a lower surface RS1 of the reflective electrode RL and an upper surface RS2 of the reflective electrode RL. In other words, the bottom surface BB of the groove GR of the separator SPR and the pixel defining layer PDL may be at a higher height than the lower surface RS1 of the reflective electrode RL and at a lower height than the upper surface RS2 of the reflective electrode RL. Here, the height may be, for example, a size from the upper surface of the ninth insulating layer INS9 in the third direction DR3.

The first bank BK1 may be located on the pixel defining layer PDL. The first bank BK1 may include a material including silicon nitride (SiNₓ). In one or more embodiments, the first bank BK1 may include a material including metal. For example, the first bank BK1 may include a material including at least one of titanium (Ti), tantalum (Ta), and/or molybdenum (Mo).

The second bank BK2 may be located on the first bank BK1. The second bank BK2 may be located on the first bank BK1 to overlap the first bank BK1. Here, the area of the second bank BK2 may be larger than the area of the first bank BK1. For example, the area of the second bank BK2 may be larger than the area of the first bank BK1 so that the second bank BK2 can surround edges of the first bank BK1 in a plan view. Accordingly, as illustrated in FIG. 9, the second bank BK2 may include tips TP not overlapping the first bank BK1, e.g., tips TP that extend past side ends of the first bank BK1 in a cross-sectional view, as shown, for example, in FIG. 9. An etch rate of the second bank BK2 may be different from an etch rate of the first bank BK1. For example, the etch rate of the first bank BK1 may be higher than the etch rate of the second bank BK2. The second bank BK2 may include a material including silicon oxide (SiOₓ).

In a cross-sectional view, the separator SPR including the first bank BK1 and the second bank BK2 may be wider at the top than at the bottom.

The light emitting stack IL may be located on the first electrodes AND, the pixel defining layer PDL, and the separator SPR. For example, the light emitting stack IL may be located on the upper portion of each first electrode AND, the third pixel defining layer PDL3 of the pixel defining layer PDL, and the second bank BK2 of the separator SPR. The light emitting stack IL may be cut on the separator SPR. For example, the light emitting stack IL may be cut between the first bank BK1 and the second bank BK2. In a plan view, the light emitting stack IL may be cut along the separator SPR. Therefore, the light emitting stack IL may be divided into a portion in contact with the first electrode AND in each emission area and a portion located on an area excluding the emission area (e.g., on the second bank BK2 of the separator SPR). In other words, the light emitting stack IL may be cut along the separator SPR so that it is separated for each subpixel. Accordingly, lateral leakage current between adjacent subpixels SP1 through SP3 can be reduce or minimized. As the lateral leakage current is reduced or minimized, a color mixing phenomenon between the adjacent subpixels SP1 through SP3 can be prevented or reduced, thereby improving the image quality of the display device 10.

The light emitting stack IL may include a plurality of stack layers stacked sequentially along the third direction DR3. For example, the light emitting stack IL may have a three-tandem structure including a first stack layer, a second stack layer on the first stack layer, and a third stack layer on the second stack layer. Here, the second stack layer may be located between the first stack layer and the third stack layer. However, the present disclosure is not limited thereto. For example, the light emitting stack IL may also have a two-tandem structure including two stack layers.

In the three-tandem structure, the first stack layer, the second stack layer, and the third stack layer of the light emitting stack IL may provide light of different colors (or wavelengths). For example, any one of the first stack layer, the second stack layer and the third stack layer may provide light of a first color (e.g., green), another stack layer may provide light of a second color (e.g., red), and the other stack layer may provide light of a third color (e.g., blue).

The first stack layer of the light emitting stack IL may have a structure in which a first hole transport layer, a first organic light emitting layer, and a first electron transport layer are sequentially stacked. The second stack layer of the light emitting stack IL may have a structure in which a second hole transport layer, a second organic light emitting layer, and a second electron transport layer are sequentially stacked. The third stack layer of the light emitting stack IL may have a structure in which a third hole transport layer, a third organic light emitting layer, and a third electron transport layer are sequentially stacked. Here, the first organic light emitting layer, the second organic light emitting layer, and the third organic light emitting layer may provide light of different colors (or wavelengths). For example, any one of the first organic light emitting layer, the second organic light emitting layer and/or the third organic light emitting layer may provide light of the first color (e.g., green), another organic light emitting layer may provide light of the second color (e.g., red), and the other organic light emitting layer may provide light of the third color (e.g., blue).

A first charge generation layer may be located between the first stack layer and the second stack layer to supply charges to the second stack layer and electrons to the first stack layer. The first charge generation layer may include an n-type charge generation layer that supplies electrons to the first stack layer and a p-type charge generation layer that supplies holes to the second stack layer. The n-type charge generation layer may include a dopant of a metallic material.

A second charge generation layer may be located between the second stack layer and the third stack layer to supply charges to the third stack layer and electrons to the second stack layer. The second charge generation layer may include an n-type charge generation layer that supplies electrons to the second stack layer and a p-type charge generation layer that supplies holes to the third stack layer.

The first stack layer of the light emitting stack IL may be located on the first electrodes AND, the pixel defining layer PDL and the separator SPR. Due to the separator SPR described above, the first stack layer of the light emitting stack IL may be broken between neighboring subpixels of subpixels SP1 through SP3. The second stack layer of the light emitting stack IL may be located on the first stack layer. Due to the separator SPR described above, the second stack layer may be broken between the neighboring subpixels of subpixels SP1 through SP3. The third stack layer of the light emitting stack IL may be located on the second stack layer. The third stack layer of the light emitting stack IL may not be broken by the separator SPR and may cover the second stack layer.

In the three-tandem structure, the separator SPR may be a structure for breaking the first charge generation layer and the second charge generation layer of the display element layer EML between neighboring subpixels of subpixels SP1 through SP3. In addition, in the two-tandem structure, the separator SPR may be a structure for breaking a charge generation layer located between a lower stack layer and an upper stack layer.

The second electrode CAT may be located on the light emitting stack IL. For example, the second electrode CAT may be located on the third stack layer of the light emitting stack IL. The second electrode CAT may be located on the third stack layer of the light emitting stack IL without being broken by the separator SPR. The second electrode CAT may include a semi-transmissive conductive material such as magnesium (Mg), silver (Ag), or an alloy of Mg and Ag. In such embodiments, the light output efficiency of each of the first through third subpixels SP1 through SP3 may be increased by a microcavity.

The encapsulation layer TFE may be located on the display element layer EML. The encapsulation layer TFE may include one or more inorganic layers TFE1 and TFE2 to prevent or reduce the penetration of oxygen or moisture into the display element layer EML. For example, the encapsulation layer TFE may include a first encapsulating inorganic layer TFE1, an encapsulating organic layer TFE2, and a second encapsulating inorganic layer TFE3.

The first encapsulating inorganic layer TFE1 may be located on the second electrode CAT. The first encapsulating inorganic layer TFE1 may be a multilayer in which one or more inorganic layers selected from among silicon nitride (SiNₓ), silicon oxynitride (SiON), and silicon oxide (SiOₓ) are alternately stacked. The first encapsulating inorganic layer TFE1 may be formed by a chemical vapor deposition process.

The encapsulating organic layer TFE2 may be located on the first encapsulating inorganic layer TFE1. The encapsulating organic layer TFE2 may be a monomer. Alternatively, the encapsulating organic layer TFE2 may be an organic layer such as acryl resin, epoxy resin, phenolic resin, polyamide resin, or polyimide resin.

The second encapsulating inorganic layer TFE3 may be located on the encapsulating organic layer TFE2. The second encapsulating inorganic layer TFE3 may be a multilayer in which one or more inorganic layers selected from among silicon nitride (SiNₓ), silicon oxynitride (SiON), and silicon oxide (SiOₓ) are alternately stacked. The second encapsulating inorganic layer TFE3 may be formed by a chemical vapor deposition process.

An organic layer APL may be a layer for increasing the interfacial adhesion between the encapsulation layer TFE and the optical layer OPL. The organic layer APL may be an organic layer such as acryl resin, epoxy resin, phenolic resin, polyamide resin, or polyimide resin.

The optical layer OPL may include a plurality of color filters CF1 through CF3, a plurality of lenses LNS, and a filling layer FIL. The color filters CF1 through CF3 may include first through third color filters CF1 through CF3. The first through third color filters CF1 through CF3 may be located on the organic layer APL.

The first color filter CF1 may overlap the first emission area EA1 of the first subpixel SP1. The first color filter CF1 may transmit light of the first color (e.g., light in the red wavelength band). Therefore, the first color filter CF1 may transmit the light of the first color among the light emitted from the light emitting stack IL of the first emission area EA1.

The second color filter CF2 may overlap the second emission area EA2 of the second subpixel SP2. The second color filter CF2 may transmit light of the second color (e.g., light in the green wavelength band). Therefore, the second color filter CF2 may transmit the light of the second color among the light emitted from the light emitting stack IL of the second emission area EA2.

The third color filter CF3 may overlap the third emission area EA3 of the third subpixel SP3. The third color filter CF3 may transmit light of the third color (e.g., light in the blue wavelength band). Therefore, the third color filter CF3 may transmit the light of the third color among the light emitted from the light emitting stack IL of the third emission area EA3.

The lenses LNS may be located on the first color filter CF1, the second color filter CF2, and the third color filter CF3, respectively. Each of the lenses LNS may be a structure for increasing the proportion of light directed to the front of the display device 10. Each of the lenses LNS may have an upwardly convex cross-sectional shape, but the present disclosure is not limited thereto.

The filling layer FIL may be located on the lenses LNS. The filling layer FIL may have a selected refractive index so that light can travel in the third direction DR3 at an interface between the lenses LNS and the filling layer FIL. In addition, the filling layer FIL may be a planarization layer. The filling layer FIL may be an organic layer such as acryl resin, epoxy resin, phenolic resin, polyamide resin, or polyimide resin.

The cover layer CVL may be located on the filling layer FIL. The cover layer CVL may be a glass substrate or polymer resin such as resin. When the cover layer CVL is a glass substrate, it may be attached onto the filling layer FIL. In such embodiments, the filling layer FIL may serve to bond the cover layer CVL. When the cover layer CVL is a glass substrate, it may serve as an encapsulation substrate. When the cover layer CVL is polymer resin such as resin, it may be directly applied on the filling layer FIL.

The polarizer POL may be located on a surface of the cover layer CVL. The polarizer POL may be a structure for preventing visibility reduction due to the reflection of external light. The polarizer POL may include a linear polarizer and a phase retardation film. For example, the phase retardation film may be a quarter-wave plate (λ/4 plate), but the present disclosure is not limited thereto. If visibility reduction due to the reflection of external light is sufficiently improved by the first through third color filters CF1 through CF3, the polarizer POL may not be provided.

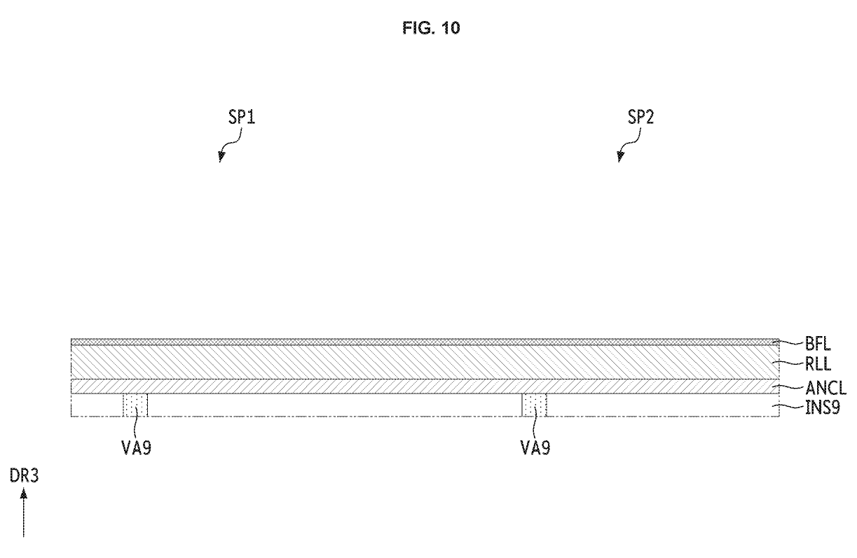

FIGS. 10-18 are process cross-sectional views illustrating a method of fabricating a display device, according to one or more embodiments of the present disclosure. For example, FIGS. 10 through 18 are process cross-sectional views illustrating a method of fabricating the display device of FIG. 9, according to one or more embodiments of the present disclosure.

First, as illustrated in FIG. 10, a ninth insulating layer INS9 may be formed on a semiconductor substrate SSUB, and ninth via electrodes VA9 may be formed in via holes of the ninth insulating layer INS9. Then, a connection electrode layer ANCL may be formed on the ninth insulating layer INS9 to contact the ninth via electrodes VA9. For example, the connection electrode layer ANCL may be formed on the entire surface of the semiconductor substrate SSUB including the ninth insulating layer INS9 and the ninth via electrodes VA9 to cover the ninth insulating layer INS9 and the ninth via electrodes VA9. Next, a reflective electrode layer RLL may be formed on the connection electrode layer ANCL. For example, the reflective electrode layer RLL may be formed on the entire surface of the semiconductor substrate SSUB including the connection electrode layer ANCL to cover the connection electrode layer ANCL. Next, a buffer layer BFL may be formed on the reflective electrode layer RLL. For example, the buffer layer BFL may be formed on the entire surface of the semiconductor substrate SSUB including the reflective electrode layer RLL to cover the reflective electrode layer RLL. The buffer layer BFL may include a material including, for example, titanium nitride (TiN).

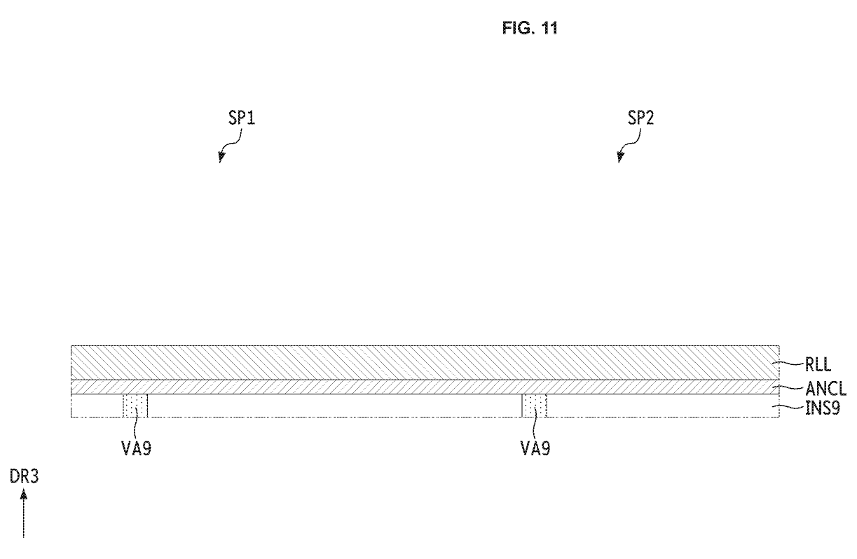

Next, as illustrated in FIG. 11, the buffer layer BFL may be patterned by a photolithography process to remove the buffer layer BFL of a display area DAA. For example, the buffer layer BFL may be patterned to form a buffer electrode on a power connection electrode in a non-display area NDA and remove the buffer layer BFL on the reflective electrode layer RLL of the display area DAA.

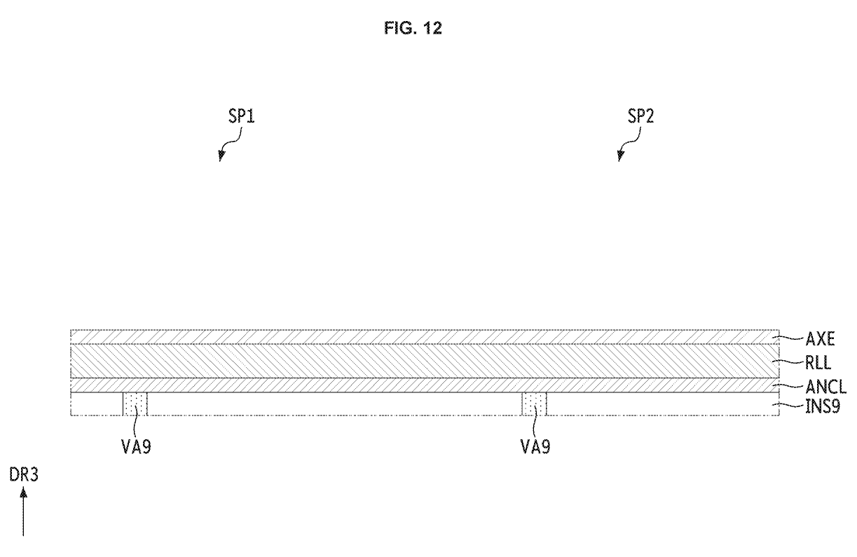

Next, as illustrated in FIG. 12, an auxiliary layer AXE may be formed on the entire surface of the semiconductor substrate SSUB including the reflective electrode layer RLL.

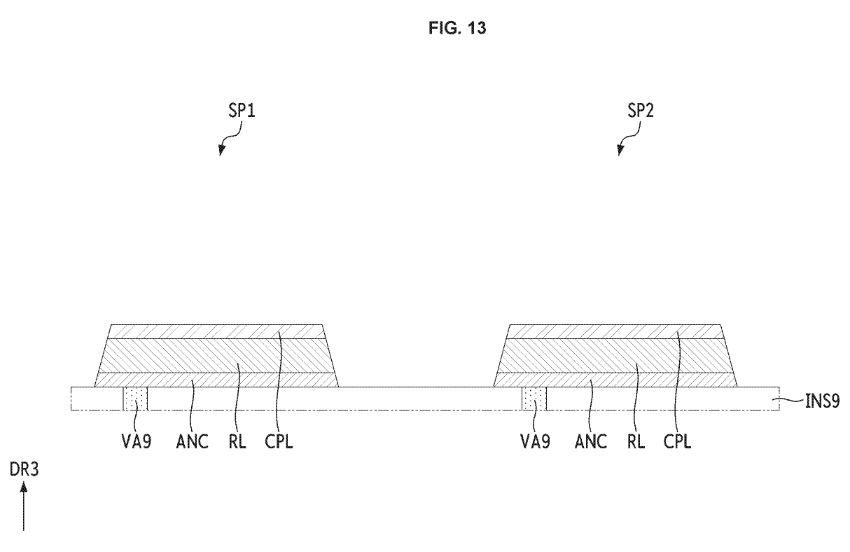

Next, as illustrated in FIG. 13, the auxiliary layer AXE, the reflective electrode layer RLL, and the connection electrode layer ANCL may be patterned by a photolithography process to form a capping layer CPL, a reflective electrode RL, and a connection electrode ANC for each subpixel SP1, SP2 and SP3. The ninth insulating layer INS9 may be exposed by the process of FIG. 13.

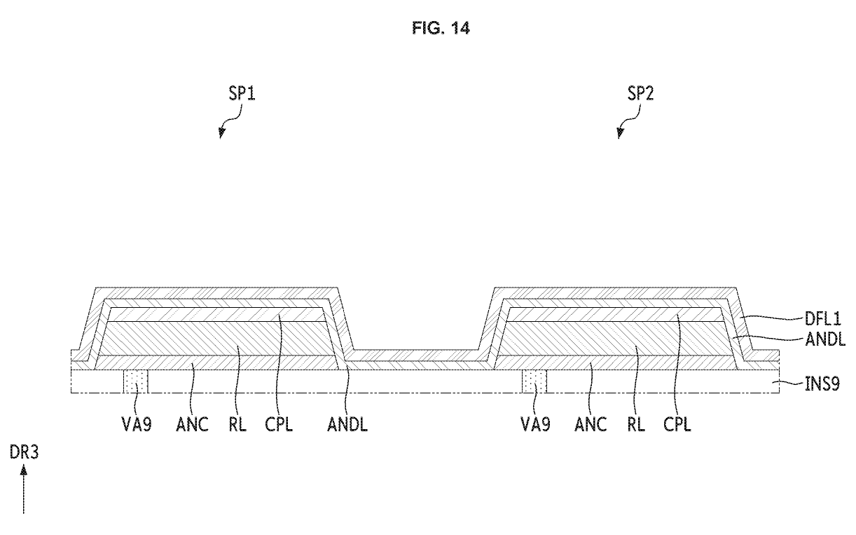

Next, as illustrated in FIG. 14, a first electrode layer ANDL may be formed on the entire surface of the semiconductor substrate SSUB including the capping layers CPL and the ninth insulating layer INS9, and then a first defining layer DFL1 may be formed on the entire surface of the semiconductor substrate SSUB including the first electrode layer ANDL.

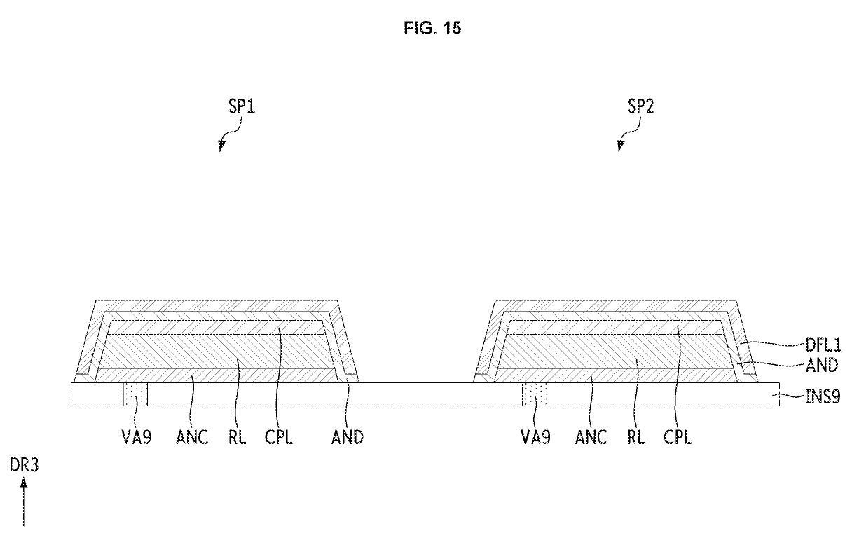

Next, as illustrated in FIG. 15, the first defining layer DFL1 and the first electrode layer ANDL may be patterned by a photolithography process to form a first defining layer DFL1 and a first electrode AND for each subpixel SP1, SP2 or SP3. The ninth insulating layer INS9 may be exposed by the process of FIG. 15.

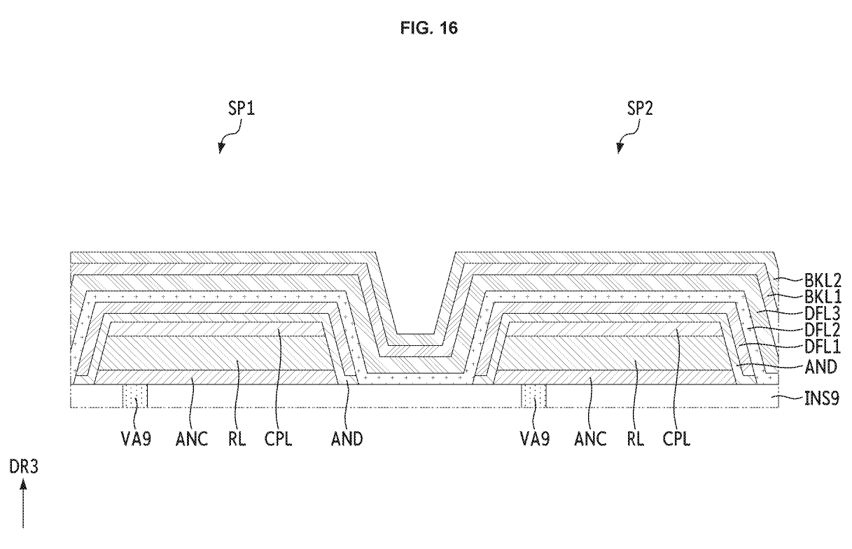

Next, as illustrated in FIG. 16, a second defining layer DFL2 may be formed on the entire surface of the semiconductor substrate SSUB including the patterned first defining layer DFL1 and the first electrodes AND. Then, a third defining layer DFL3 may be formed on the entire surface of the semiconductor substrate SSUB including the second defining layer DFL2. Next, a first bank layer BKL1 may be formed on the entire surface of the semiconductor substrate SSUB including the third defining layer DFL3, and then a second bank layer BKL2 may be formed on the entire surface of the semiconductor substrate SSUB including the first bank layer BKL1.

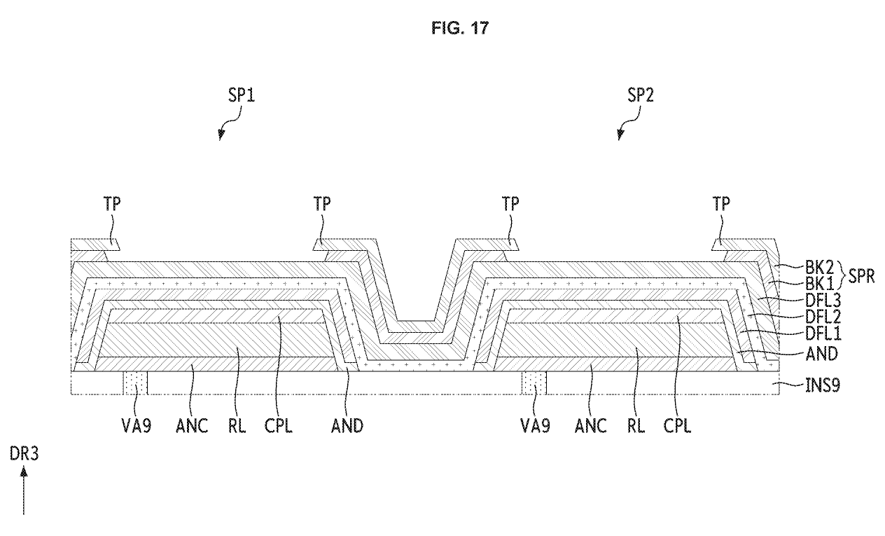

Next, as illustrated in FIG. 17, the second bank layer BKL2 and the first bank layer BKL1 may be patterned together by a photolithography process to form a second bank BK2 and a first bank BK1 having a reverse tapered shape. The third defining layer DFL3 may be exposed in each subpixel SP1, SP2 or SP3 by the process of FIG. 17.

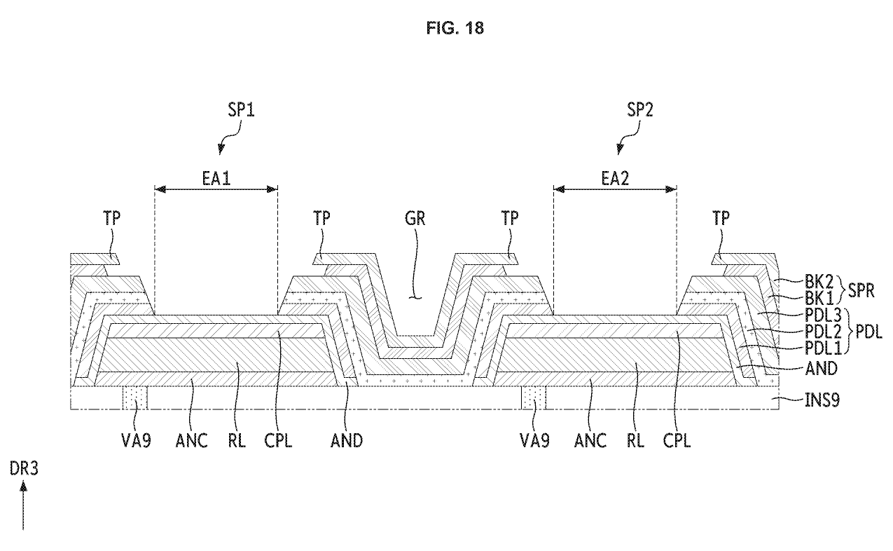

Next, as illustrated in FIG. 18, the third defining layer DFL3, the second defining layer DFL2, and the first defining layer DFL1 may be patterned by a photolithography process to form a pixel defining layer PDL and expose the first electrode AND of each subpixel. For example, the pixel defining layer PDL may include a first emission area EA1 exposing the first electrode AND of a first subpixel SP1, a second emission area EA2 exposing the first electrode AND of a second subpixel SP2, and a third emission area EA3 exposing the first electrode AND of a third subpixel SP3.

According to one or more embodiments, a separator SPR and the pixel defining layer PDL may each have a groove GR between the subpixels SP1 through SP3 (e.g., between adjacent first electrodes AND of adjacent subpixels of subpixels SP1 to SP3). For example, since the pixel defining layer PDL is formed by a patterning process such as photolithography without a planarization process (e.g., a chemical mechanical polishing process), it may have the groove GR between adjacent first electrodes AND. In addition, since the pixel defining layer PDL has the groove GR, the separator SPR on the pixel defining layer PDL may also have the groove GR.

According to one or more embodiments, since the pixel defining layer PDL is formed without a planarization process (e.g., a chemical mechanical polishing process), damage to the reflective electrodes RL due to hillocks of the reflective electrodes RL can be prevented or reduced. For example, aluminum used as a material of each reflective electrode RL may cause a hillock of the reflective electrode RL during the above-described process. Accordingly, a portion of the reflective electrode RL may penetrate a capping layer CPL and form a protrusion that rises above the capping layer CPL. Then, a first electrode AND located on the capping layer CPL and the pixel defining layer PDL (e.g., a first pixel defining layer PDL1) located on the first electrode AND may also rise due to the hillock of the reflective electrode RL. Therefore, the hillock may be damaged during a process of planarizing the first pixel defining layer PDL1 through chemical mechanical polishing. Then, during a cleaning process, a cleaning solution (e.g., a diluted hydrofluoric acid solution) may come into contact with the damaged hillock. In such embodiments, the cleaning solution (e.g., the diluted hydrofluoric acid solution) may penetrate into the reflective electrode RL along the damaged hillock. In such embodiments, a portion of the reflective electrode RL may be damaged. For example, a portion of the reflective electrode RL may be melted and removed. If a portion of the reflective electrode RL is melted and removed, a hole may be formed in the removed portion. Consequently, a hole may be formed in a portion of the reflective electrode RL, and the hole of the reflective electrode RL may be recognized as a defect in the form of a black dot in the display area DAA. Therefore, the image quality of the display device 10 may deteriorate. However, according to one or more embodiments of the present disclosure, since the display device is fabricated without the process of planarizing the pixel defining layer PDL (e.g., the first pixel defining layer PDL1), damage to the reflective electrodes RL can be prevented.

Next, as illustrated in FIG. 9, a light emitting stack IL may be formed on the first electrodes AND, the pixel defining layer PDL and the separator SPR, a second electrode CAT may be formed on the light emitting stack IL, and an encapsulation layer TFE may be formed on the second electrode CAT. Here, the light emitting stack IL may be separated for each subpixel SP1, SP2 or SP3 by the separator SPR.

The display device 10 according to one or more embodiments can be applied to various electronic devices. An electronic device according to one or more embodiments includes the above-described display device 10 and may further include modules or devices having other additional functions, in addition to the display device 10.

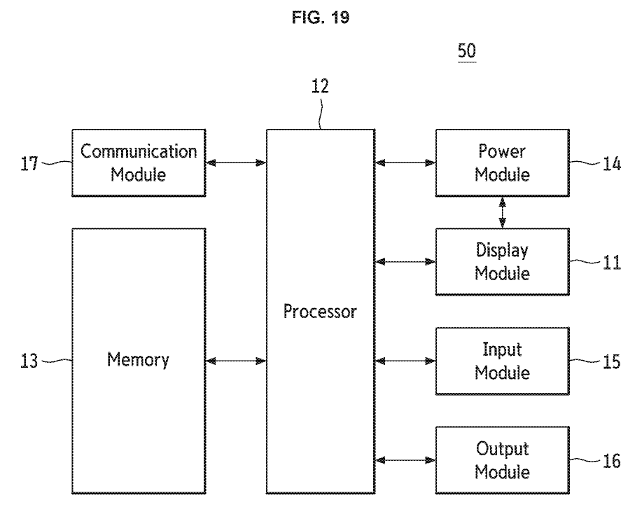

FIG. 19 is a block diagram of an electronic device 50 according to one or more embodiments of the present disclosure. Referring to FIG. 19, the electronic device 50 according to one or more embodiments may include a display module 11, a processor 12, a memory 13, and a power module 14. The electronic device 50 may further include an input module 15, a non-image output module 16, and/or a communication module 16.

The electronic device 50 may output various information in the form of images through the display module 11. When the processor 12 executes an application stored in the memory 13, image information provided by the application may be provided to a user through the display module 11. The power module 14 may include a power supply module such as a power adapter or a battery device and a power conversion module which generates power necessary for the operation of the electronic device 50 by converting power supplied by the power supply module. The input module 15 may provide input information to the processor 12 and/or the display module 11. The non-image output module 15 may receive non-image information, such as sound, haptic and/or light, from the processor 12 and provide the information to a user. The communication module 16 is a module that is responsible for transmitting and receiving information between the electronic device 50 and an external device and may include a receiving unit and a transmitting unit.

At least one of the elements of the electronic device 50 described above may be included in a display device according to one or more embodiments described above. In addition, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 50.

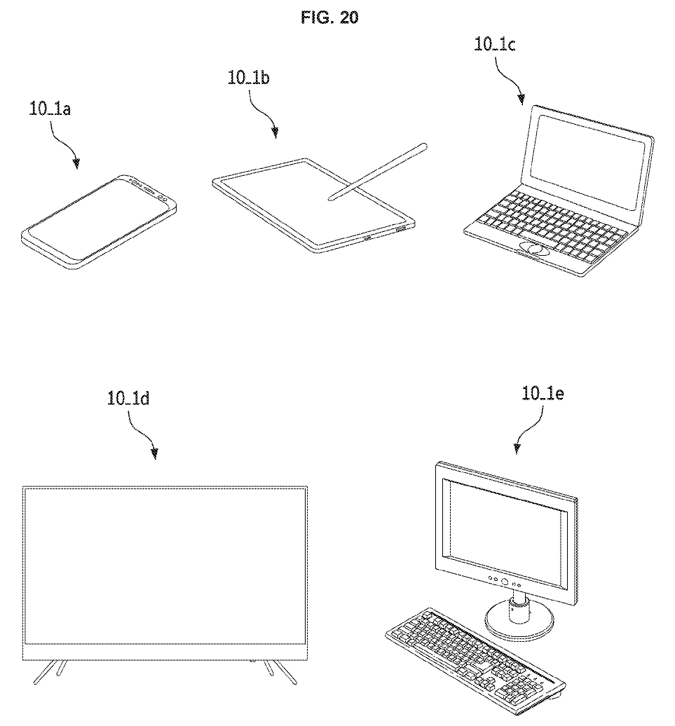

FIGS. 20, 21, and 22 are schematic diagrams of electronic devices according to embodiments of the present disclosure. FIGS. 20 through 22 illustrate examples of various electronic devices to which a display device 10 according to embodiments is applied.

FIG. 20 illustrates a smartphone 10_1a, a tablet PC 10_1b, a laptop 10_1c, a television 10_1d, and a desk monitor 10_1e as examples of electronic devices.

The smartphone 10_1a may include an input module such as a touch sensor and a communication module in addition to a display module 11. The smartphone 10_1a may process information received through the communication module or other input modules and display the information through a display module of a display device.

Like the smartphone 10_1a, the tablet PC 10_1b, the laptop 10_1c, the television 10_1d, and the desk monitor 10_1e may also include a display module and an input module and may further include a communication module in some embodiments.

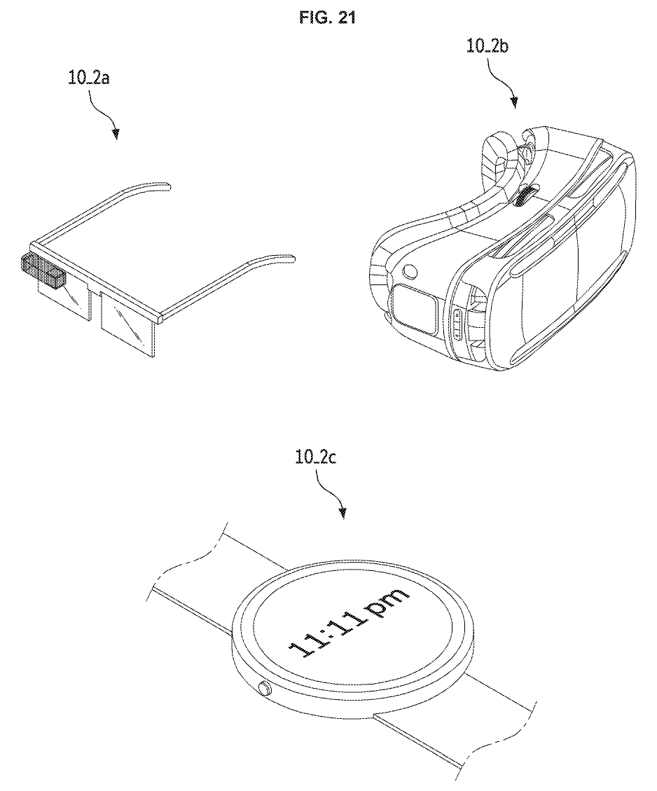

FIG. 21 illustrates embodiments in which an electronic device including a display module is applied to a wearable electronic device. The wearable electronic device may be smart glasses 10_2a, a head mounted display 10_2b, a smart watch 10_2c, or the like.

The smart glasses 10_2a and the head mounted display 10_2b may include a display module which outputs a display image and a reflector which provides the output display screen to a user’s eyes by reflecting the output display screen. Accordingly, a screen of virtual reality or augmented reality can be provided to the user.

The smart watch 10_2c may include a biometric sensor as an input device and may provide biometric information recognized by the biometric sensor to a user through a display module.

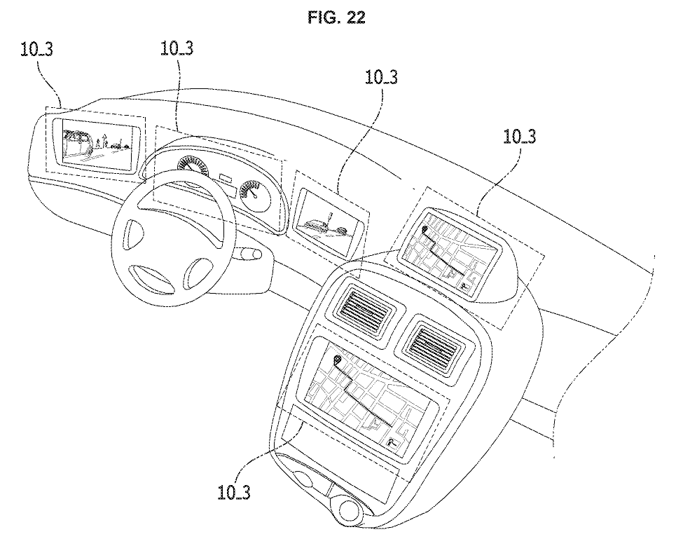

FIG. 22 illustrates a case where an electronic device including a display module is applied to a vehicle. For example, an electronic device 10_3 may be applied to an instrument panel, center fascia, etc., of a vehicle, may be applied to a center information display (CID) located on a dashboard of the vehicle, or may be applied to a room mirror display replacing a side mirror.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ± 30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate having a display area in which a plurality of subpixels are located, each subpixel of the plurality of subpixels comprising:
a connection electrode on the display area of the substrate;
a reflective electrode on the connection electrode;
a capping layer on the reflective electrode; and
a first electrode on the capping layer;
a pixel defining layer on each of the first electrodes of the plurality of subpixels and defining emission areas, the emission areas exposing the first electrodes;
a light emitting stack on the first electrodes and the pixel defining layer; and
a second electrode on the light emitting stack,
wherein the pixel defining layer defines a groove between adjacent first electrodes of the first electrodes.

2. The display device of claim 1, wherein the groove is sunken toward the substrate.

3. The display device of claim 1, wherein the pixel defining layer comprises:
a first pixel defining layer on the first electrode;
a second pixel defining layer on the first pixel defining layer; and
a third pixel defining layer on the second pixel defining layer.

4. The display device of claim 3, wherein the first pixel defining layer has a discontinuous cross-section between the adjacent first electrodes.

5. The display device of claim 3, wherein the second pixel defining layer has a continuous cross-section between the adjacent first electrodes.

6. The display device of claim 3, wherein the third pixel defining layer has a continuous cross-section between the adjacent first electrodes.

7. The display device of claim 1, further comprising a separator on the pixel defining layer.

8. The display device of claim 7, wherein the separator defines a groove.

9. The display device of claim 8, wherein the groove of the separator is sunken toward the substrate.

10. The display device of claim 9, wherein the groove of the separator and the groove of the pixel defining layer are coextensive.

11. The display device of claim 10, wherein a bottom surface of the groove of the separator and the pixel defining layer is located at a height between a lower surface of the reflective electrode and an upper surface of the reflective electrode.

12. The display device of claim 7, wherein the separator comprises:
a first bank on the pixel defining layer; and
a second bank located on the first bank and having a larger area than the first bank.

13. The display device of claim 12, wherein an etch rate of the first bank is higher than an etch rate of the second bank.

14. The display device of claim 1, wherein the capping layer has the same thickness in the emission areas and the emission areas are to emit light of different colors.

15. The display device of claim 1, wherein the first electrode is on an upper surface of the capping layer, side surfaces of the capping layer, side surfaces of the reflective electrode, and side surfaces of the connection electrode.

16. The display device of claim 15, wherein a thickness of the first electrode on the side surfaces of the capping layer is different from a thickness of the first electrode on the upper surface of the capping layer.

17. The display device of claim 1, wherein the thickness of the first electrode on the side surfaces of the capping layer is smaller than the thickness of the first electrode on the upper surface of the capping layer.

18. An electronic device comprising:
a display device comprising a screen, wherein the display device comprises:
a substrate having a display area in which a plurality of subpixels are located, each subpixel of the plurality of subpixels comprising:
a connection electrode on the display area of the substrate;
a reflective electrode on the connection electrode;
a capping layer on the reflective electrode; and
a first electrode on the capping layer;
a pixel defining layer on each of the first electrodes of the plurality of subpixels and defining emission areas, the emission areas exposing the first electrodes;
a light emitting stack on the first electrodes and the pixel defining layer; and
a second electrode on the light emitting stack,
wherein the pixel defining layer defines a groove between adjacent first electrodes of the first electrodes.

19. The electronic device of claim 18, comprising a smartphone, a tablet, a laptop, a television, a desk monitor, smart glasses, a smart watch, a head mounted display, and a vehicle.

20. A method of fabricating a display device comprising a plurality of subpixels, the method comprising:
forming a connection electrode layer on an insulating layer on a substrate;
forming a reflective electrode layer on the connection electrode layer;
forming a buffer layer on the reflective electrode layer;
removing the buffer layer on a display area of the substrate by patterning the buffer layer;
forming an auxiliary layer on an entire surface of the substrate comprising the reflective electrode layer;
forming a capping layer, a reflective electrode and a connection electrode for each subpixel of the plurality of subpixels and exposing the insulating layer by patterning the auxiliary layer, the reflective electrode layer, and the connection electrode layer;
forming a first electrode layer on the entire surface of the substrate comprising the capping layer and the insulating layer;
forming a first defining layer on the entire surface of the substrate comprising the first electrode layer;
forming a first defining layer and a first electrode for each subpixel and exposing the insulating layer by patterning the first defining layer and the first electrode layer;
forming a second defining layer on the entire surface of the substrate comprising the patterned first defining layer and the first electrode;
forming a third defining layer on the entire surface of the substrate comprising the second defining layer;
forming a first bank layer on the entire surface of the substrate comprising the third defining layer;
forming a second bank layer on the entire surface of the substrate comprising the first bank layer;
forming a separator having a first bank and a second bank and exposing the third defining layer in each subpixel by patterning the second bank layer and the first bank layer together; and
forming a pixel defining layer having emission areas which expose the first electrode of each subpixel by patterning the third defining layer, the second defining layer, and the first defining layer,
wherein the pixel defining layer has a groove between adjacent first electrodes of the first electrodes of the plurality of subpixels.
